(19) United States
(12) Patent Application Publication
(10) Pub. No.: US 2026/0201282 A1
(43) Pub. Date: Jul. 16, 2026

(54) CLEANING COMPOSITION FOR ORGANIC AND INORGANIC MATERIALS, METHOD FOR CLEANING USING THE SAME AND ELECTRONIC DEVICE MANUFACTURED USING THE SAME

(71) Applicants: Samsung Display Co., LTD., Yongin-si (KR); POONG WON CHEMICAL CO., LTD., Ansan-si (KR)

(72) Inventors: JUNGSUN PARK, Yongin-si (KR); SEUNGYONG SONG, Yongin-si (KR); AREUM LEE, Yongin-si (KR); JOONGU LEE, Yongin-si (KR); JUNG HUN YOO, Yongin-si (KR); TAE JOON SUL, Yongin-si (KR); KI YOUNG LEE, Yongin-si (KR); YOUNG MIN LIM, Yongin-si (KR)

(21) Appl. No.: 19/339,657

(22) Filed: Sep. 25, 2025

(30) Foreign Application Priority Data
Jan. 15, 2025 (KR) 10-2025-0005968

(51) Int. Cl. C11D 7/32

(52) U.S. Cl. CPC C11D 7/3281; C11D 7/3263; C11D 2111/22

(57) ABSTRACT

A cleaning composition for an organic or inorganic material, a cleaning method using the cleaning composition, and an electronic device manufactured using the cleaning method. Particularly, a cleaning composition for an organic or inorganic material includes an amide-based compound and an amine-based compound in a certain volume ratio and having more advanced cleaning performance, drying capability and PNL reliability than a conventional OLED cleaning agent.

### CROSS-REFERENCE TO RELATED APPLICATION

This application claims priority to and the benefit of Korean Patent Application No. 10-2025-0005968, filed on Jan. 15, 2025, in the Korean Intellectual Property Office, and all the benefits accruing therefrom under 35 U.S.C. § 119, the contents of which are incorporated herein in its entirety by reference.

### BACKGROUND

### Field

The present disclosure relates to a cleaning composition for an organic or inorganic material, a cleaning method using the cleaning composition, and an electronic device manufactured using the cleaning composition.

Due to many advantages of an organic light-emitting diode (OLED), such as a fast response speed, a low power consumption, and a wide visibility angle, a demand for organic light-emitting diodes has dramatically increased. In order to form an organic material layer for such an organic light-emitting diode, a mask is used. An organic material deposited on a surface of the mask may cause a defect in the formation of a pattern of the organic light-emitting diode. In order to prevent the defect from forming, a cleaning solution is used to remove the organic material deposited on the surface of the mask. However, the cleaning solution may leave a residue after cleaning, or cleaning is not properly performed and leaves a residue, which may significantly affect reliability in a manufacturing process of an organic light-emitting diode.

A conventional cleaning solution may have low cleaning efficiency. Even if it has high cleaning efficiency, it may cause human toxicity or environmental pollution.

### SUMMARY

There is a problem that the cleaning solution remains after cleaning. Accordingly, there is a need for a cleaning solution that provides a high cleaning efficiency and minimizes the cleaning solution that remains on a surface after cleaning of the mask.

The present disclosure seeks to provide a cleaning composition for cleaning an organic or inorganic material, a cleaning method using the cleaning composition, and an electronic device manufactured using the cleaning composition.

The present disclosure is not limited to the embodiments described herein, and additional embodiments may be clearly understood by a person ordinarily skilled in the art from the following descriptions.

Embodiments of the present disclosure include a composition for cleaning an organic or inorganic material. The composition may include an amide-based compound, and an amine-based compound, a volume ratio of the amide-based compound to the amine-based compound may be 1:1 to 1:99, the amide-based compound may be an amide-based compound represented by Formula 1 below, and the amine-based compound may be an amine-based compound represented by Formula 2 below.

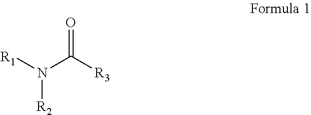

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may form 5- to 8-membered cyclic rings.

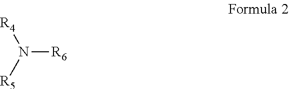

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, or a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

In one or more embodiments of the present disclosure, the heterocyclic compound may be piperazine, pyrazine, morpholine, pyrone, pyrazole, imidazole, isoxazole, oxazole, isothiazole, thiazole, triazole, indole, quinoline, benzothiazole, or benzooxazole, but the present disclosure is not limited thereto.

In one or more embodiments of the present disclosure, the amide-based compound may be a compound of Formula 1 where R₁ through R₃ each is an unsubstituted C1 to C20 alkyl group, the amine compound may be a compound of Formula 2 where R₄ through R₆ each is a C1 to C10 alkyl group including a heterocyclic compound having 5 to 20 ring-forming atoms, wherein the heterocyclic compound may be a pyrazine, a morpholine, pyrone, pyrazole, imidazole, isoxazole, oxazole, isothiazole, thiazole, or triazole, but the present disclosure is not limited thereto.

In one or more embodiments of the present disclosure, the amide-based compound may be N,N-dimethylpropionamide, N,N-dimethylisobutylamide, N,N-dimethylacrylamide, N,N-dimethylmethacrylamide, N-ethylformamide, N,N-diethylformamide, N,N-diethylacetamide, N,N-diethylpropionamide, N,N-diethylisobutylamide, N,N-diethylacrylamide, N,N-diethylmethacrylamide, 3-methoxy-N,N-dimethylpropionamide, 3-butoxy-N,N-dimethylpropionamide, or a combination thereof, but the present disclosure is not limited thereto.

In one or more embodiments of the present disclosure, the amine-based compound may be N-(3-aminopropyl)morpholine, 1-amino-benzotriazole, 2-amino-benzotriazole, or a combination thereof, but the present disclosure is not limited thereto.

In one or more embodiments of the present disclosure, the cleaning composition may be for cleaning an OLED deposition mask, but the present disclosure is not limited thereto.

In one or more embodiments of the present disclosure, the cleaning composition for an organic or inorganic material may be for cleaning an organic material composed of a light-emission layer, a light-emission host material, a dopant, a hole transport layer HTL, a hole blocking layer HBL, a hole injection layer EIL, or a capping layer CPL, but the present disclosure is not limited thereto.

In one or more embodiments of the present disclosure, the cleaning composition for an organic or inorganic material may be for removing a silicon-based polymer, a color resist, an organic insulating film, or a resin, but the present disclosure is not limited thereto.

In one or more embodiments of the present disclosure, the organic material may be pthalocyanine derivative, a phenylamine derivative, a phenoxybenzene derivative, a carbazolyl derivative, a polyaniline derivative, a starburst amine derivative, a porphyrin derivative, an oligothiphene derivative, an arylamine derivative, a hexanitrilehexaazatriphenylene derivative, a quinacridone derivative, a perylene derivative, an anthraquinone, a polythiophene derivative, or a combination thereof, but the present disclosure is not limited thereto.

In one or more embodiments of the present disclosure, the cleaning composition for an organic or inorganic material may further include a water-soluble polar solvent, but the present disclosure is not limited thereto.

In one or more embodiments of the present disclosure, the water-soluble polar solvent may be included in an amount of 5 to 50 volume % with respect to 100 volume % of the cleaning composition, but the present disclosure is not limited thereto.

In one or more embodiments of the present disclosure, the cleaning composition for an organic or inorganic material may further include water, and the water may be included in an amount of less than or equal to 1 volume % with respect to 100 volume % of the cleaning composition for an organic or inorganic material, but the present disclosure is not limited thereto.

In one or more embodiments of the present disclosure, a boiling point of the amide-based compound, amine-based compound or a combination thereof may be greater than or equal to 100° C. and less than or equal to 300° C., but the present disclosure is not limited thereto.

In one or more embodiments of the present disclosure, the cleaning composition for an organic or inorganic material may further include a pH adjusting agent, but the present disclosure is not limited thereto.

A cleaning method of an organic or inorganic material according to another aspect of the present disclosure may include a cleaning process of cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

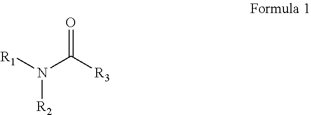

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may form 5- to 8-membered cyclic rings.

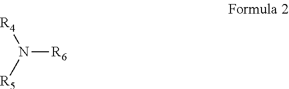

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, or a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

In one or more embodiments of the present disclosure, the amide-based compound may be a compound of Formula 1 where R₁ through R₃ each is an unsubstituted C1 to C20 alkyl group, the amine compound may be a compound of Formula 2 where R₄ through R₆ each is a C1 to C10 alkyl group including a heterocyclic compound having 5 to 20 ring-forming atoms, the heterocyclic compound may be a pyrazine, a morpholine, pyrone, pyrazole, imidazole, isoxazole, oxazole, isothiazole, thiazole, or triazole, but the present disclosure is not limited thereto.

In one or more embodiments of the present disclosure, the cleaning process may be cleaning through a dipping, spraying, ultrasonic, heating, or steam cleaning process.

In one or more embodiments of the present disclosure, the cleaning process may allow cleaning at a temperature greater than or equal to 0° C. and less than or equal to 80° C.

In one or more embodiments of the present disclosure, a process time of the cleaning process may be longer than or equal to 50 seconds and shorter than or equal to 3600 seconds.

According to another aspect of the present disclosure, an electronic device is manufactured through a manufacturing method including a cleaning process for cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

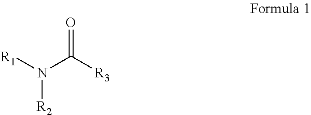

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ is not a hydrogen atom, and the R₁ through R₃ may form 5- to 8-membered cyclic rings.

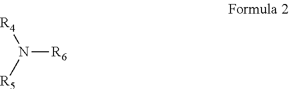

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

In one or more embodiments of the present disclosure, the electronic device may include a display device, a processor configured to control the display device, a memory configured to store data necessary for operation of the display device or the processor, and a power module configured to generate or supply power, but the present disclosure is not limited thereto.

In one or more embodiments of the present disclosure, the electronic device may be any one of electronic devices, such as a flat panel display, a curved display, a television, a billboard, a computer monitor, a medical monitor, a head mounted display (HMD), an indoor or outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual or augmented reality display, a video wall including multiple displays tiled together, a vehicle, an outdoor display device, a theater or a stadium screen, a scoreboard, a signboard, and home appliances that display information through a display module, such as a refrigerator, a washing machine, a dryer, an air conditioner, and a robot vacuum cleaner. However, a type of an electronic device according to one or more embodiment of the present disclosure is not limited to the above examples, and various electronic devices other than the above examples may be also applicable.

According to another aspect of the present disclosure, a manufacturing method of an electronic device includes a cleaning process for cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

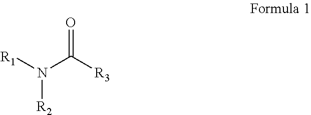

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may form 5- to 8-membered cyclic rings.

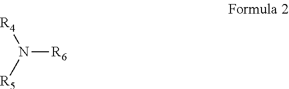

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

A cleaning composition for an organic or inorganic material according to one or more embodiment may have excellent cleaning capability, be harmless to a human being, and minimize environmental toxicity.

A cleaning composition for an organic or inorganic material according to one or more embodiment may minimize a cleaning composition remaining on a surface after cleaning an organic or inorganic material.

However, effects of the present disclosure are not limited to the above effects but may be variously extended in a scope without departing from the spirit and scope of the present disclosure.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a plan view illustrating a display device according to one embodiment of the present disclosure;

FIG. 2 is a cross-sectional view taken along the I-I′ line shown in FIG. 1;

FIG. 3 through FIG. 6 are cross-sectional views illustrating a light-emitting diode according to one embodiment;

FIG. 7 and FIG. 8 are cross-sectional views illustrating portions of a display device according to one embodiment of the present disclosure;

FIG. 9 is a graph of a PNL reliability evaluation result of Comparative Example 1 and Comparative Example in which the average of reliability evaluation as a function of time according to one embodiment of the present disclosure;

FIG. 10 is a graph showing a PNL reliability evaluation result of Comparative Example 1 and Example 1 in which the average of reliability evaluation as a function of time according to one embodiment of the present disclosure;

FIG. 11 is a block diagram of an electronic device according to one embodiment of the present disclosure; and

FIG. 12 through FIG. 14 are schematic diagrams of an electronic device according to various embodiments of the present disclosure.

### DETAILED DESCRIPTION

References will now be made in more detail to certain embodiments, of which examples are illustrated in the accompanying drawings, where like reference numerals refer to like elements throughout the disclosure, and duplicative descriptions thereof may not be provided for conciseness. The presented embodiments may have a variety of forms and permutations, but the present disclosure shall by no means be construed as being limited to the described embodiments. Rather, the present disclosure shall be construed to encompass all form, permutations, equivalents, and substitutes covered by the technical ideas and scope of the present disclosure. Accordingly, one or more embodiments are merely described, by referring to the drawings, to explain features of the present disclosure and to convey the scope of the disclosure to those skilled in the art.

Unless otherwise defined, all technical terms and scientific terms used herein have the same meaning as how they are generally understood by those of ordinary skill in the art to which the present disclosure pertains. However, if (e.g., when) the meanings do not match, a description, including a definition, of the present disclosure takes precedence.

Terms such as “first” and “second” may be used in describing one or more suitable elements, but the elements shall not be restricted to the terms. The terms may be used only to distinguish one element from the other. For instance, the first element may be named the second element, and vice versa, without departing the scope of the present disclosure. Unless clearly used otherwise, any expressions in a singular form may include a meaning of a plural form. For example, the singular forms “a,” “an,” “one,” and “the” are intended to include the plural forms as well, unless the context clearly indicates otherwise. The term “and/or” or “or” as used herein shall include the combination of a plurality of listed items or any of the plurality of listed items. Further, the utilization of “may” when describing embodiments of the present disclosure refers to “one or more embodiments of the present disclosure.”

When an element is described to be “on,” “placed on,” “arranged on,” “connected to,” or “coupled to” another element, it shall be construed as being on, placed on, arranged on, connected to, or coupled to the other element directly but also as possibly having another element arranged between the element and the other element. In contrast, if (e.g., when) one element is described to be “directly on,” “directly placed on,” “directly arranged on,” “directly connected to,” or “directly coupled to” another element, it shall be construed that there is no other element arranged between the element and another element.

An expression such as “comprise(s)/comprising”, “include(s)/including”, or “has(have)/having” is intended to designate a characteristic, a number, a step (e.g., act or task), an operation, an element, a part, and/or one or more (e.g., any suitable) combinations thereof, and shall not be construed to preclude any possibility of presence or addition of one or more other characteristics, numbers, steps, operations, elements, parts, and/or one or more (e.g., any suitable) combinations thereof. Additionally, the terms “comprise(s)/comprising,” “include(s)/including,” “has(have)/having,” or other similar terms include or support the terms “consisting of” and “consisting essentially of,” indicating the presence of stated features, integers, steps, operations, elements, components, and/or groups, without or essentially without the presence of other features, integers, steps, operations, elements, components, and/or groups thereof.

Any reference to “and/or” shall be construed to include one or more combinations that can be defined by relevant elements. A size and a thickness of each configuration illustrated in a drawing is shown as an example for convenience, and embodiments of the present disclosure are not limited thereto.

As used herein, a direct linkage may refer to a chemical bond, such as a single bond.

As used herein, examples of halogens may include fluorine, chlorine, bromine, and iodine.

As used herein, a “substituted or unsubstituted” group may be a group unsubstituted or substituted with at least one substituent that may be deuterium, a halogen, a nitro group, an amine group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group, a heterocyclic group, or a combination thereof. In addition, each of the substituents presented as examples above may be substituted or unsubstituted. For example, a biphenyl group may be interpreted as an aryl or as a phenyl group substituted with a phenyl group.

As used herein, the phrases “the R₁ through R₃ may form 5- to 8-membered cyclic rings, and “the R₄ through R₆ may form 5- to 8-membered cyclic rings,” “forming a ring by combining with an adjacent group,” and/or the like may refer to forming a substituted or unsubstituted hydrocarbon ring or a substituted or unsubstituted heterocycle by combining one at least two, or all three, of the named groups, preferably with an adjacent group. The hydrocarbon ring includes an aliphatic hydrocarbon ring and/or an aromatic hydrocarbon ring. The heterocycle includes an aliphatic heterocycle and/or an aromatic heterocycle. The carbon ring and the heterocycle may each be a monocycle or a polycycle. In addition, the formed ring may be combined with another ring to form a spiro structure.

As used herein, a fluorenyl group may be substituted, and two substituents may be combined to form a spiro structure with the fluorenyl group.

As used herein, the phrase “an adjacent group” may refer to a substituent connected to an atom which is directly connected to another atom substituted with another substituent; a substituent connected to an atom which is substituted with another substituent; or a substituent sterically positioned at the nearest position to another substituent. For example, two methyl groups in 1,2-dimethylbenzene may be interpreted as an “adjacent group” to each other.

As used herein, an alkyl group may have a linear chain or a branched chain. The number of carbons in the alkyl group may be 1 to 30, 1 to 20, or 1 to 10. Non-limiting examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl.

As used herein, a cycloalkyl group may refer to a cyclic alkyl group. The number of carbons in the cycloalkyl group may be 3 to 50, 3 to 30, or 3 to 10. Non-limiting examples of the cycloalkyl group may include cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, or bicycloheptyl, but the present disclosure is not limited thereto.

As used herein, an alkenyl group may refer to a hydrocarbon group including one or more carbon-carbon double bonds in the middle and/or at the terminal of an alkyl group having 2 or more carbons. An alkenyl group may have a linear chain or a branched chain. The number of carbons in the alkenyl group may be, but not limited to, 2 to 30, 2 to 20 or 2 to 10. Non-limiting examples of the alkenyl group may include 1-butenyl, 1-pentenyl, 1,3-butadienyl aryl, and styrenyl.

As used herein, an alkynyl group may refer to a hydrocarbon group including one or more carbon-carbon triple bonds in the middle and/or at the terminal of an alkyl group having 2 or more carbons. The number of carbons in the alkynyl group may be, but not limited to, 2 to 30, 2 to 20 or 2 to 10. Non-limiting examples thereof may include ethynyl and propynyl.

As used herein, an aryl group refers to a functional group or a substituent derived from an aromatic hydrocarbon ring. The aryl group may be a monocyclic aryl or a polycyclic aryl. The aryl group may have 6 to 60, 6 to 30, 6 to 20, or 6 to 15 ring-forming carbons. Non-limiting examples of the aryl group may include a phenyl group, a fluorenyl group, an anthracenyl group, a naphthyl group, a terphenyl group, a biphenyl group, a sexiphenyl group, a triphenylenyl group, and a benzofluoranthenyl group.

As used herein, a heterocyclic group (i.e., a heterocyclic group) may refer to any functional group or substituent derived from a ring including at least one of B, O, N, P, Si, or S as a ring-forming heteroatom. The heteroring group may include an aliphatic heteroring group and/or an aromatic heteroring group. The aromatic heteroring group may be a heteroaryl group. The aliphatic heteroring and the aromatic heteroring may each be monocyclic or a polycyclic.

As used herein, if (e.g., when) the heterocyclic group includes two or more heteroatoms, the two or more heteroatoms may be identical to or different from each other. The heterocyclic group may be a monocyclic heteroring or a polycyclic heteroring and includes a heteroaryl group. The heterocyclic group may have 2 to 30, 2 to 20, 2 to 10, 2 to 5, or 2 to 4 ring-forming carbons.

As used herein, an aliphatic heterocyclic group may include at least one of B, O, N, P, Si, or S as a ring-forming heteroatom. The aliphatic heterocyclic group may have 2 to 30, 2 to 20, or 2 to 10, or 2 to 5, or 2 to 4 ring-forming carbons. Non-limiting examples of the aliphatic heterocyclic group may include a thiirane group, a pyrrolidine group, a piperidine group, a tetrahydrofuran group, and 1, 4-dioxane group.

As used herein, a heteroaryl group may include at least one of B, O, N, P, Si, or S as a ring-forming atom. When the heteroaryl group includes two or more heteroatoms, the two or more heteroatoms may be identical to or different from each other. The heteroaryl group may be a monocyclic heteroring or a polycyclic heteroring. The heteroaryl group may have 2 to 60, 2 to 30, 2 to 20, or 2 to 10 ring-forming carbons. Non-limiting examples may include a furan group, a pyrrole group, an imidazole group, a pyridine group, a pyrimidine group, a triazine group, a pyridazine group, a quinoline group, an isoquinoline group, a pyridopyrimidine group, a benzocarbazole group, a benzofuran group, and an oxazole group.

As used herein, the above description of the aryl group may be applied to an arylene group, except that the arylene group is a polyvalent group (e.g., a divalent group). The above description of the heteroaryl may be applied to a heteroarylene group, except that the heteroarylene group is a polyvalent group (e.g., a divalent group). A polyvalent group may refer to, but not limited to, a trivalent or quadrivalent group.

As used herein, a silyl group may include an alkyl silyl group and/or an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, and a phenylsilyl group.

As used herein, a thio group may include an alkyl thio group and/or an aryl thio group. A thio group may indicate a group in which a sulfur atom is bonded to an alkyl or an aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthiol group, and a naphthylthio group.

As used herein, an oxy group may indicate a group in which an oxygen atom is bonded to an alkyl group or an aryl group defined above. The oxy group may include an alkoxy group and/or an aryloxy group. An alkoxy group may be linear, branched, or cyclic. The number of carbon atoms in the alkoxy group is not particularly limited, but may be, for example, 1 to 20, or 1 to 10. Non-limiting examples of the oxy group may include a methoxy, an ethoxy, a n-propoxy, an isopropoxy, a butoxy, a pentyloxy, a hexyloxy, an octyloxy, a nonyloxy, a decyloxy, and a benzyloxy.

As used herein, the number of carbon atoms in an amine group is not particularly limited, but may be 1 to 30. The amine group may include an alkyl amine group and/or an aryl amine group. Non-limiting examples of the amine group may include a methylamine group, a dimethylamine group, a phenylamine group, a diphenylamine group, a naphthylamine group, a 9-methyl-anthracenylamine group, and a triphenylamine group.

Hereinafter, embodiments of the present disclosure will be explained with reference to the figures. In the descriptions with reference to the figures, a same or corresponding component will be applied with a same figure reference, and a redundant thereof will be omitted.

A cleaning composition for an organic or inorganic material according to one aspect of the present disclosure may include an amide-based compound and an amine-based compound, a volume ratio of the amide-based compound to the amine-based compound may 1:1 to 1:99, the amide-based compound may be an amide-based compound represented by Formula 1 below, and the amine-based compound may be an amine-based compound represented by Formula 2 below.

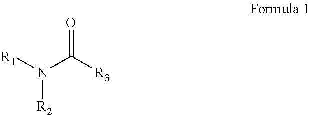

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, i.e., there may be maximum two hydrogen atoms substituents for the R₁ through R₃, and the R₁ through R₃ may form 5- to 8-membered cyclic rings. As described above, two or three of R₁, R₂, and R₃ may be joined together to form a ring.

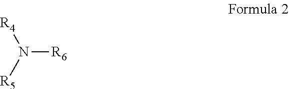

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms. There may be at least one of R₄ through R₆ that is not a hydrogen atom, e.g., there may be a maximum of two hydrogen atoms substituents for the R₄ through R₆, and the R₄ through R₆ may form 5- to 8-membered cyclic rings. As described above, two or three of R₄, R₅, and R₆ may be joined together to form a ring.

In one or more embodiments of the present disclosure, the heterocyclic compound may be piperazine, pyrazine, morpholine, pyrone, pyrazole, imidazole, isoxazole, oxazole, isothiazole, thiazole, triazole, indole, quinoline, benzothiazole, or benzooxazole, but the present disclosure is not limited thereto.

In order to manufacture a display including an organic light-emitting diode, a conventional open metal mask (OMM) and/or a fine metal mask (FMM) may be utilized. The open metal mask may be used for deposition of an organic material layer on a front surface of a display, the organic layer having a function on an organic light-emitting diode substrate. The fine metal mask may be used for deposition of various color components of red color, green color, and blue color with a high-resolution on a sub-pixel during a manufacturing process of an organic light-emitting diode display.

For example, in case that a fine metal mask is used for deposition of a color component, millions of fine holes through which an organic material may pass are precisely positioned on a frame and fixed by laser to be aligned close to a substrate, and an organic material vaporized by heat is deposited on the fine metal mask hole. A surface of the mask needs to be cleaned due to accumulation of a deposition source and an organic material. In addition, a degree of cleaning the mask has a high correlation with a quality and process efficiency of the organic light-emitting diode.

In addition, a mask is also used for deposition of a second electrode EL2 composed of metal and a capping layer CPL composed of an organic layer. Materials used for the second electrode EL2 and the capping layer CPL may be deposited on the mask used for this process. The mask is to be re-used to save costs for a manufacturing process and increase efficiency. If cleaning efficiency of a cleaning composition is low or a cleaning composition remains on a surface, efficiency of a deposition process decreases, and eventually qualities of a manufactured organic light-emitting diode and display therefrom may be affected.

Using a cleaning composition for an organic and inorganic material according to the present disclosure, it becomes possible to manufacture a high-quality organic light-emitting diode and display by providing excellent cleaning capability for an organic material and/or inorganic material accumulated on a mask after performance of a deposition process and minimizing a remaining cleaning composition to increase cleaning efficiency.

Although the present disclosure is not limited thereto, a volume ratio of the amide-based compound to the amine-based compound may be adjusted based on cleaning capability for an organic material. A volume ratio of the amide-based compound to the amine-based compound of a cleaning composition for organic or inorganic materials according to present disclosure may be 1:1 to 1:99. Within the above range of the volume ratio, cleaning capability for various organic materials may be excellent, and high synergic effect between the amide-based compound and amine-based compound may be shown. In addition, within the above range of volume ratio, an amount of the cleaning composition remaining on a surface after cleaning of a mask may be minimized. The volume ratio of the amide-based compound to the amine-based compound may be suitably 1:1.5 to 1:49, and more suitably 1:4 to 1:20, but the present disclosure is not limited thereto.

A cleaning composition for inorganic and organic materials of the present disclosure may include the amide-based compound and the amine-based compound in a specific ratio to have excellent cleaning capability for various deposition materials on a mask without damaging intrinsic components of the mask. Accordingly, using a cleaning composition of the present disclosure may allow cleaning organic or inorganic materials on a mask without damaging the mask.

In case that the volume ratio of the amine-based compound is out of the above range, cleaning capability of a cleaning composition for organic or inorganic materials of the present disclosure may be lowered due to pH, and a manufacture yield of OLED may be lowered accordingly.

The amide-based compound may have excellent solubility for a deposition material on a mask and increase a detachment speed, but the present disclosure is not limited thereto. Particularly, the amide-based compound of the present disclosure may have excellent solubility for a deposition material.

The amine-based compound may be configured to, but not limited to, break a bond of a cured deposition material or organic material to dissolve a polymer and prevent re-adsorption after washing to increase cleaning capability.

In addition, a cleaning composition for organic or organic materials of the present disclosure may have excellent dryness than a conventional cleaning composition for OLED to minimize a cleaning composition remaining on a surface after cleaning of a mask. Particularly, a cleaning composition for organic or inorganic materials of the present disclosure may have excellent permeability because of a lower surface tension that a conventional cleaning composition for OLED and be advantageous in drying a gap in a mask.

Because an environmentally hazardous material, such as N-methyl-pyrrolidone (NMP), which is harmful to a human being and highly, environmentally toxic, is not used, a cleaning composition for organic or inorganic materials according to the present disclosure is not toxic to a human being and does not cause environment pollution.

In one embodiment of the present disclosure, the amide-based compound may be a compound of Formula 1 where R₁ through R₃ each is an unsubstituted C1 to C20 alkyl group, the amine compound may be a compound of Formula 2 where R₄ through R₆ each is a C1 to C10 alkyl group including a heterocyclic compound having 5 to 20 ring-forming atoms, and the heterocyclic compound may be a pyrazine, a morpholine, pyrone, pyrazole, imidazole, isoxazole, oxazole, isothiazole, thiazole, or triazole, but the present disclosure is not limited thereto.

The amide-based compound may be selected from, for example, N,N-dimethylpropionamide (DMPA), N,N-dimethylisobutylamide, N,N-dimethylacrylamide, N,N-dimethylmethacrylamide, N-ethylformamide, N,N-diethylformamide, N,N-diethylacetamide, N,N-diethylpropionamide, N,N-diethylisobutylamide, N,N-diethylacrylamide, N,N-diethylmethacrylamide, 3-methoxy-N,N-dimethylpropionamide, 3-butoxy-N,N-dimethylpropionamide, and a combination thereof, but the present disclosure is not limited thereto.

The amine-based compound may be selected from, but not limited to, N-(3-aminopropyl)morpholine, 1-amino-benzotriazole, 2-amino-benzotriazole and a combination thereof.

A cleaning composition for organic or inorganic materials according to the present disclosure may be used for, but not limited to, cleaning a material deposited on a mask used in a manufacturing process of OLED. The mask deposition material used in a manufacturing process of OLED may be, but not limited to, for example, an organic material forming a light-emission layer configured to emit red light, green light, blue light, or white light, a light-emission host material, a dopant, a hole transport layer HTL, a hole block layer HBL, an electron injection layer EIL, or a capping layer CPL.

The material forming a light-emission layer, light-emission host material, hole transport layer HTL, hole block layer HBL, electron injection layer EIL, or capping layer CPL may be, but not limited to, a known material.

A material for a light-emission layer may be, but not limited to, for example, an anthracene derivative, a fluoranthene derivative, a chrysene derivative, a pyrene derivative, a dihydrobenzanthracene derivative, a triphenylene derivative, a bisstyrylbenzene derivative, tris-(8-quinolinolato)aluminum (Alq₃), bis[2-(2-benzooxazolyl)phenolate]zinc (II) (Zn-PBO), rubrene, dimethylquinacridone, N,N′-dimethylquinacridone (DMQ), or 4-(dicyanomethylene)-2-methyl-6-[2-(2,3,6,7-tetrahydro-1H,5H-benzo[ij]quinolidine-9-yl)vinyl]-4H-pyran (DCM2). The material for a light-emission layer may be, but not limited to, a quantum dot which is a semiconductor compound crystalline having various light-emission color, such as blue, red, and green.

The light-emission host material may use a compound represented by Formula EM-1 below as a fluorescence light-emission host material, but the present disclosure is not limited thereto.

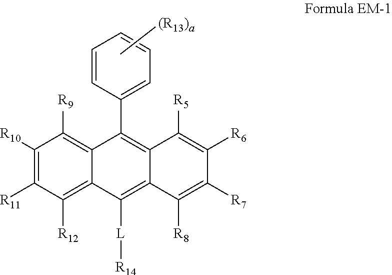

In Formula EM-1, L may be direct linkage, a substituted or unsubstituted arylene group having 6 to 30 ring-forming carbons, or a substituted or unsubstituted heteroarylene group having 2 to 30 ring-forming carbons. Unlimiting examples may be a phenylene group, a biphenylene group, a terphenylene group, a naphthalene group, a phenanthrene group, a pyrene group, a spirofluorenylene group, a fluorenylene group, dibenzofuranylene group, dibenzothiophenylene group, or a carbazolylene group.

In Formula EM-1, R₅ through R₁₄ may each independently be a hydrogen, deuterium, a halogen, a substituted or unsubstituted oxy group, a substituted or unsubstituted thio group, a substituted or unsubstituted silyl group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bond to an adjacent group to form a ring. In Formula EM-1, a may be an integer greater than or equal to 0 and smaller than or equal to 5. An anthracene compound represented by Formula EM-1 may be E20, but the present disclosure is not limited to.

In one embodiment, in the light-emission layer EML, a compound represented by Formula EM-2 or Formula EM-3 below may be used as a phosphorescence host material.

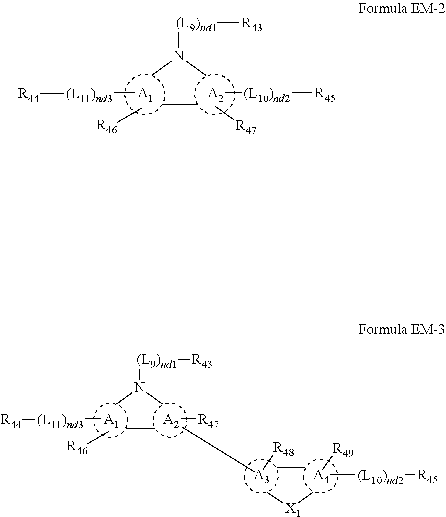

In Formula EM-2 and Formula EM-3, ring A₁ through ring A₄ may each independently be a substituted or unsubstituted aryl group having 6 to 30 ring-forming carbons, or a substituted or unsubstituted heteroaryl group having 2 to 30 ring-forming carbons. Examples may include a benzene, a naphthalene, a phenanthrene, a fluoranthene, a triphenylene, a pyrene, a pyridine, a pyrimidine, an indene, a fluorene, a spiro-bifluorene, a benzofluorene, a dibenzofluorene, an indol, a carbazole, a benzocarbazole, a dibenzocarbazole, a furan, a benzofuran, a dibenzofuran, a benzonaphthofuran, a benzothiophene, a dibenzothiophene, a benzonaphthothiophene, or dinaphthothiophene.

Further in Formula EM-2 and Formula EM-3, nb1 and nb3 may each independently be, but not limited to, 0, 1, or 2. X₁ may be O, S, N-L₁₂-R₅₀, CR₅₁R₅₂, and SiR₅₃R₅₄. L₉ through L₁₂ may each independently be a direct linkage, a substituted or unsubstituted arylene group having 6 to 30 ring-forming carbons, or a substituted or unsubstituted heteroarylene group having 2 to 30 ring-forming carbons.

Also in Formula EM-2 and Formula EM-3, R₄₃ through R₄₉ and R₅₀ through R₅₄ may each independently be hydrogen, deuterium, a halogen, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons.

The light-emission layer EML may further include a material generally suitable in the field as a host material. For example, in one or more embodiments, the light emitting layer EML may include at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), Bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi) as a host material. However, embodiments of the present disclosure are not limited thereto, for example, a host material, such as tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethylbiphenyl (CDBP), 2-Methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), and/or octaphenylcyclotetrasiloxane (DPSiO₄), may be used.

A material of the hole transport layer HTL may include, but is not limited to, a compound represented by Formula H-1 below, a compound represented by Formula H-2 below, or a combination thereof.

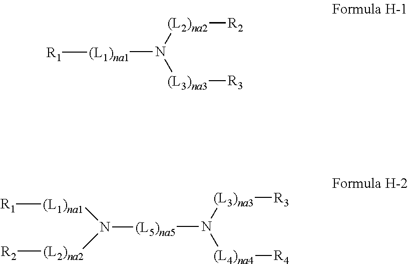

In Formula H-1 and Formula H-2, L₁ through L₅ may each independently be a direct linkage, a substituted or unsubstituted arylene group having 6 to 30 ring-forming carbons, or a substituted or unsubstituted heteroarylene group having 2 to 30 ring-forming carbons; na1 and na4 may each independently be an integer greater than or equal to 0 and smaller than or equal to 5; and na5 may be an integer greater than or equal to 1 and smaller than or equal to 10.

In Formula H-1 and Formula H-2, R₁ through R₄ may each independently be a hydrogen, a deuterium, a halogen, a substituted or unsubstituted alkyl group having 1 to 20 carbons, a cycloalkyl group having 3 to 10 carbons, a substituted or unsubstituted heterocycloalkyl group having 1 to 20 carbons, a substituted or unsubstituted cycloalkenyl group having 3 to 10 carbons, a substituted or unsubstituted heterocycloalkenyl group having 1 to 10 carbons, a substituted or unsubstituted aryl group having 6 to 60 carbons, a substituted or unsubstituted aryloxy group having 6 to 60 carbons, a substituted or unsubstituted arylthio group having 6 to 60 carbons, a substituted or unsubstituted heteroaryl group having 1 to 60 carbons.

For example, in Formula H-1 and H-2, R₁ through R₄ may each independently be, for example, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, a fluoranthenyl group, a triphenylenyl group, a pyrenyl group, a perylenyl group, a pentaphenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group and a pyridinyl group, but the present disclosure is not limited thereto.

In Formula H-1 and Formula H-2, R₁ and R₂ may be optionally bonded to each other via a single bond, and/or R₃ and R₄ may be optionally bonded to each other via a single bond.

A compound represented by Formula H-1 or Formula H-2 may be a carbazole-based compound having a substituted or unsubstituted carbazole group at least one of R₁ through R₄, or a fluorene-based compound having a substituted or unsubstituted fluorene group at least one of R₁ through R₄.

A compound represented by any of Formula H-1 or Formula H-2 may be shown as, but not limited to, HT3 or HT40 among compounds presented in a device manufacture example of the present disclosure.

In one or more embodiments, a material of the hole transport layer HTL may include, but not limited to, for example, 4,4′,4″-tris{N,-(2-naphthyl)-N-phenylamino}-triphenylamine (2-TNATA), poly(3,4-ethylenedioxythiophene)/Poly(4-styrenesulfonate) (PEDOT/PSS), 4,4′,4″-tris(3-methylphenylphenylamino) triphenylamine (m-MTDATA), 4,4′4″-tris(N,N-diphenylamino)triphenylamine (TDATA), a phthalocyanine compound, such as copper phthalocyanine, N,N′-diphenyl-N,N′-bis-[4-(phenyl-m-tolyl-amino)-phenyl]-biphenyl-4,4′-diamine (DNTPD), polyaniline/dodecylbenzenesulfonic acid (PANI/DBSA), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], or dipyrazino[2,3-f: 2′,3′-h]quinoxaline-2,3,6,7,10,11-hexacarbonitrile (HAT-CN).

In one or more embodiments, a material of the hole transport layer HTL may include, but not limited to, a polyvinylcarbazole, a carbazole-based derivative, such as N-phenylcarbazole, a fluorene-based derivative, a triphenylamine-based derivative, such as 4,4′4″-tris(N-carbazolyl)triphenylamine (TCTA) and N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), Alq₃, 1,3-Bis(N-carbazolyl)benzene (mCP), 2,9-dimethyl-4,7-diphenyl-1,10-phenanthroline (BCP), 2-(4-Biphenylyl)-5-phenyl-1,3,4-oxadiazole (PBD), a silole derivative, or a combination thereof.

In addition, a material of a hole transport layer HTL may include, but not limited to, for example, 1,3-bis(1,8-dimethyl-9H-carbazol-9-yl)benzene (mDCP), 9-(4-tert-Butylphenyl)-3,6-bis(triphenylsilyl)-9H-carbazole (CzSi), or 9-phenyl-9H-3,9′-bicarbazole (CCP).

A material of the hole block layer HBL may include, but is not limited to, a compound represented by Formula ET-1 below.

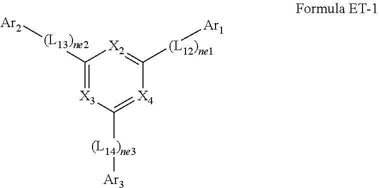

In Formula ET-1, Ar₁ through Ar₃ may each independently be hydrogen, deuterium, a halogen, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons. Non-limiting examples thereof may be a phenyl group, a naphthyl group, a biphenyl group, a phenanthrene group, a fluorene group, a spirofluorene group, a terphenyl group, a pyridine group, a carbazole group, or an isoquinoline group.

At least one of X₂, X₃ or X₄ may be N and the others may be CRₐ.

Rₐ may be hydrogen, deuterium, a halogen, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In Formula ET-1, ne1 through ne3 may each independently be an integer greater than or equal to 0 and smaller than or equal to 5.

In Formula ET-1, L₁₂ through L₁₄ may each independently be a direct linkage, a substituted or unsubstituted arylene group having 6 to 30 ring-forming carbons, or a substituted or unsubstituted heteroarylene group having 2 to 30 ring-forming carbons. In addition, in case that ne1 through ne3 are integers greater than or equal to 2, L₁₂ through L₁₄ may each independently be a substituted or unsubstituted arylene group having 6 to 30 ring-forming carbons, or a substituted or unsubstituted heteroarylene group having 2 to 30 ring-forming carbons.

A material of the hole injection layer HIL may include, but not limited to, copper phthalocyanine (CuPC), a poly(3,4-ethylenedioxythiophene) (PEDOT) and polystyrenesulfonate (PSS) complex (PEDOT/PSS), a 4,4′,4″-tris[phenyl(m-tolyl)amino]triphenylamine (m-MTDATA), or a combination thereof. A material of the hole block layer HBL may include, but not limited to, for example, 2,9-dimethyl-4,7-diphenyl-1,10-phenanthroline (BCP), tris(8-hydroxyquinolinato)aluminum (Alq₃), bis(2-methyl-8-quinolinolato-N1,O8)-(1,1′-biphenyl-4-olato)aluminum (BAlq), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), berylliumbis(benzoquinolin-10-olate) (Bebg2), 9,10-di(naphthalene-2-yl)anthracene (ADN), 1,3-Bis[3,5-di(pyridin-3-yl)phenyl]benzene (BmPyPhB), or any combination thereof.

A material of the electron injection layer (EIL) may include, but not limited to, an alkaline earth metal, a rare earth metal, an alkali metal, an alkaline earth metal-containing compound, a rare earth metal-containing compound, an alkali metal-containing compound, an alkaline earth metal complex, a rare earth metal complex, an alkali metal complex or any combination thereof only, or include an organic material. The organic material may further include, but not limited to, for example, at least one of a compound represented by the Formula EM-2 or Formula EM-3, 2,9-dimethyl-4,7-diphenyl-1,10-phenanthroline (BCP), diphenyl(4-(triphenylsilyl)phenyl)phosphine oxide (TSPO1) and 4,7-diphenyl-1,10-phenanthroline (Bphen).

As a material for the capping layer (CPL), it is not limited to this, but it can be an organic layer or an inorganic layer. When the capping layer (CPL) includes inorganic materials, it is not limited to this, but the inorganic materials may include alkali metal compounds such as LiF, alkaline earth metal compounds such as MgF₂, SiON, SiNₓ, SiO_{y}, or combinations thereof.

A material of the capping layer CPL may be, but not limited to, an organic layer or an inorganic layer. In case that the capping layer CPL includes an inorganic material, the inorganic material may be an alkaline metal compound, such as LiF, an alkaline earth metal compound, such as MgF₂, SiON, SiNₓ, SiO_{y}, or a combination thereof, but the present disclosure is not limited thereto.

In case that the capping layer CP1 includes an organic material, the organic material may include an amine compound, such as monoamine or diamine, but the present disclosure is not limited thereto. For example, TPD, α-NPD, β-NPB, m-MTDATA, N4, N4, N4′, N4′-tetra (biphenyl-4-yl) biphenyl-4,4′-diamine (TPD15), 4,4′4″-tris(carbazol-9-yl) triphenylamine (TCTA) may be included for example. However, the present disclosure is not limited thereto, and the capping layer CPL may include Alq₃, CuPc, an epoxy resin, or an acrylate, such as methacrylate.

A deposition material on a mask in addition to the above may be a dopant material known in the field. The dopant material may be a fluorescence dopant material and/or phosphorescence dopant material. The fluorescence dopant material may be, not but limited to, for example, a perylene and a derivative thereof (e.g., 2, 5, 8, 11-Tetra-t-butylperylene (TBP)), a pyrene and a derivative thereof (e.g., 1, 1-dipyrene, 1, 4-dipyrenylbenzene, and 1, 4-Bis(N, N-diphenylamino)pyrene), a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N,N-phenylbenzenamine (NBDAVBi)), or 4,4′-bis[2-(4-(N,N-diphenylamino) phenyl)vinyl]biphenyl(DPAVBi).

The phosphorescence dopant material may be, but not limited to, a known phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as the phosphorescence dopant. Particularly, iridium(III) bis(4,6-difluorophenylpyridinato-NC2′)picolinate (FIrpic), bis(2,4-difluorophenylpyridinato)-tetrakis(1-pyrazolyl)borate iridium(III) (Fir6), or platinum octaethyl porphyrin (PtOEP) may be used as phosphorescence dopant. However, an embodiment of the present disclosure is not limited thereto.

In addition, the cleaning composition for organic or inorganic materials may be, but not limited to, for removing a silicon-based polymer, a color resist, an organic insulating film, or a resin.

The organic material may be selected from, but not limited to, a phthalocyanine derivative, a phenylamine derivative, a phenoxybenzene derivative, a carbazolyl derivative, a polyaniline derivative, a starburst amine derivative, a porphyrin derivative, an oligothiophene derivative, an arylamine derivative, a hexanitrile hexaazatriphenylene derivative, a quinacridone derivative, a perylene derivative, an anthraquinone, a polythiophene derivative, and a combination thereof.

The cleaning composition for organic or inorganic materials may further include, but not limited to, a water-soluble polar solvent.

The water-soluble polar solvent may assist in dissolving an organic or inorganic material remaining on a mask and preventing attachment of a deposition material to further improve cleaning capability. The water-soluble polar solvent may be selected according to a required performance in a cleaning process. The water-soluble polar solvent may be selected from, but not limited to, for example, ethyleneglycol monomethyl ether, ethyleneglycol monoethyl ether, ethyleneglycol, monoisopropyl ether, ethyleneglycol monobutyl ether, diethyleneglycol monomethyl ether, diethyleneglycol monoethyl ether, diethyleneglycol monoisopropyl ether, diethyleneglycol monobutyl ether, triethyleneglycol monomethyl ether, triethyleneglycol monoethyl ether, triethyleneglycol monoisopropyl ether, triethyleneglycol, monobutyl ether, polyethyleneglycol monomethyl ether, polyethyleneglycol monobutyl ether, propyleneglycol monomethyl ether, dipropyleneglycol monomethyl ether, tripropyleneglycol monomethyl ether, tetrahydrofurfuryl alcohol, 4-hydroxymethyl-1,3-dioxolan, 4-hydroxymethyl-2,2-dimethyl-1,3-dioxolan, 4-hydroxyethyl-2,2-dimethyl-1,3-dioxolan, 4-hydroxypropyl-2,2-dimethyl-1,3-dioxolan, 4-hydroxybutyl-2,2-dimethyl-1,3-dioxolan, 4-hydroxymethyl-2,2-diethyl-1,3-dioxolan, 4-hydroxymethyl-2-methyl-2-ethyl-1,3-dioxolan, and a combination thereof.

The cleaning composition for organic or inorganic materials may be for, but not limited to, removing a material deposited on a mask in a deposition process with a second electrode material or a capping layer material of OLED. The organic material may be selected from, but not limited to, a phthalocyanine derivative, a phenylamine derivative, a phenoxybenzene derivative, a carbazolyl derivative, a polyaniline derivative, a starburst amine derivative, a porphyrin derivative, an oligothiophene derivative, an arylamine derivative, a hexanitrile hexaazatriphenylene derivative, a quinacridone derivative, a perylene derivative, an anthraquinone, a polythiophene derivative, and a combination thereof.

The water-soluble polar solvent may be included in an amount of 5 to 50 volume %, 10 to 45 volume %, or 10 to 35 volume % with respect to 100 volume % of the cleaning composition. In case that the water-soluble polar solvent is included in an amount within the above range, cleaning effects for dissolving organic or inorganic materials may be excellent, and subsequent removal of cleaning solution may be easy. Furthermore, water may be rapidly removed when drying after cleaning.

A cleaning composition for organic or inorganic materials of the present disclosure may further include, but not limited to, water. The water may be included in an amount of less than or equal 1 volume % with respect to 100 volume % of the cleaning composition for organic or inorganic materials. In case that an amount of water satisfies the above range, cleaning may be proceeded easily without affecting organic light emission. The water may be, but not limited to, distilled water, deionized water, or ultrapure water. For example, in case that deionized water is included in the cleaning composition of the present disclosure, activation of the amine-based compound may be improved, and a cleaning speed of a deposition material, particularly an insoluble material, may be increased. In addition, the deionized water may combine with a water-soluble polar solvent to quickly remove a deposition material without any residue during a rinsing process.

A boiling point of the amide-based compound, amine-based compound or a combination thereof may be, but not limited to, 100 to 300° C. The boiling point of the amide-based compound, amine-based compound or a combination thereof may satisfy the above range to reduce a wasted amount of the cleaning composition due to vaporization during a cleaning process and be advantageous also in a process environmental aspect.

The cleaning composition for organic or inorganic materials may further include, but not limited to, a pH adjusting agent. In case that a deposition material is an insoluble material, for example, in a particle form, the pH adjusting agent may adjust pH of the cleaning composition and improve cleaning capability, but the present disclosure is not limited thereto. Non-limited examples of the pH adjusting agent may be an inorganic base, such as ammonium hydroxide, sodium hydroxide, potassium hydroxide, or strong acid, such as hydriodic acid, hydrobromic acid, sulfuric acid, sulfurous acid, nitric acid, hydrochloric acid, chromic acid, phosphoric acid, acetic acid, and sulfonic acid.

A cleaning method of an organic or inorganic material according to one embodiment of the present disclosure may include a cleaning process of cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

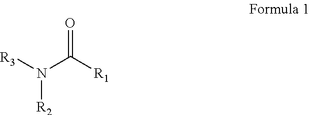

In Formula 1, R₁ through R₃ may each be independently be a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may optionally form one or more 5- to 8-membered cyclic rings.

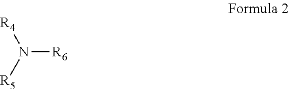

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

The amide-based compound may be, but not limited to a compound of Formula 1 where R₁ through R₃ each is an unsubstituted C1 to C20 alkyl group, the amine compound may be a compound of Formula 2 where R₄ through R₆ each is a C1 to C10 alkyl group including a heterocyclic compound having 5 to 20 ring-forming atoms, for example wherein the heterocyclic compound may be a pyrazine, a morpholine, pyrone, pyrazole, imidazole, isoxazole, oxazole, isothiazole, thiazole, or triazole, but the present disclosure is not limited thereto.

The cleaning method includes a cleaning process, a rinsing process and a drying process. In the cleaning process, a cleaning composition for an organic or inorganic material may be used to clean a mask. The mask after the cleaning process may be rinsed with a rinsing composition, and dried through the drying process as necessary.

A subject mask in the cleaning process may have been, but not limited to, used in a vacuum deposition process. A light-emission layer corresponding to R, G and B is formed as a display device on a substrate in a vacuum chamber. A mask having an opening corresponding to a shape of the light-emission layer is disposed, a material of the light-emission layer is heated and evaporated, and a material is deposited on a surface of the substrate. During the deposition process, a large amount of the deposition materials are attached on the mask.

The cleaning process may be, but not limited to, cleaning performed by dipping, spray, ultrasound, heat, or steam.

The cleaning process may be performed, but not limited to, at a temperature higher than or equal to 0° C. and less than or equal to 80° C. By cleaning at a temperature within the above range, cleaning capability may be improved, and a damage to a mask due to heat may be prevented. In addition, a cleaning process time may be adjusted in consideration of a mask size, and a type and amount of an attached organic material. The cleaning process time may be, but not limited to, longer than or equal to 50 seconds and less than or equal to 3600 seconds.

A cleaning composition to be used in the cleaning process according to the present disclosure may allow cleaning of a large amount of deposition materials merely by one type of composition, and therefore, different types of cleaning tanks may not be required for cleaning. In addition, the cleaning composition may not affect a rinsing composition. The cleaning composition may be easily removed as the cleaning composition may dissolve well in the rinsing composition. The cleaning composition may be reused because the cleaning composition is not disintegrated by the rinsing composition. The rinsing composition may be selected from known compositions. A non-limiting example of the rinsing composition may be HEF-347pc-f including hydrofluoroether.

The drying process after the rinsing process may be, but not limited to, drying a mask through natural drying, drying by air blow, or drying by decompression. Drying by air blow may be suitable. The drying by air blow may be, but not limited to, drying by spraying dry air at a temperature higher than or equal to 10° C. and less than or equal to 40° C. Upon the spraying dry air, a damage to a mask due to heat may be prevented.

An electronic device according to one embodiment is manufactured through a manufacturing method including a cleaning process for cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

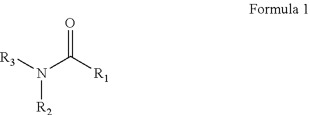

In Formula 1, R₁ through R₃ may each be independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may form 5- to 8-membered cyclic rings.

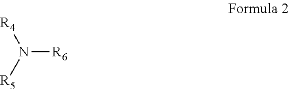

In Formula 2, R₄ through R₆ may each be independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C1 to C10 alkenyl group including a heterocyclic compound having 5 to 20 ring-forming atoms, and a C1 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

A display device and an electronic device according to one embodiment of the present disclosure will be explained with reference to figures.

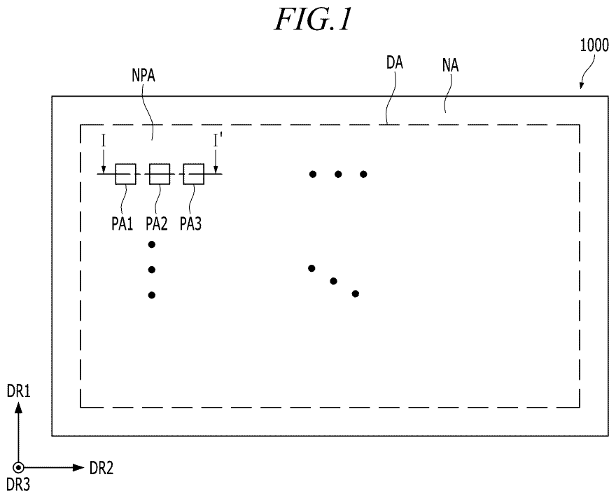

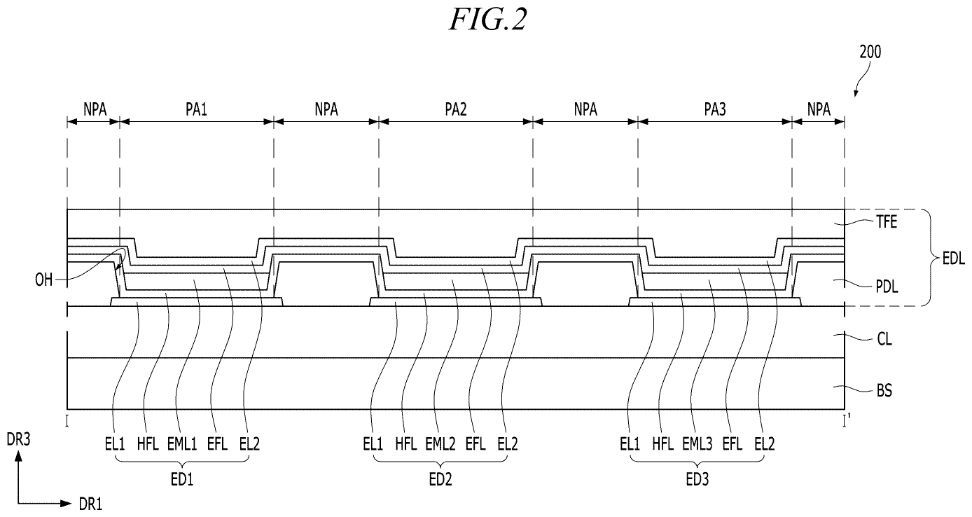

FIG. 1 is a plan view illustrating a display device according to one embodiment of the present disclosure, and FIG. 2 is a cross-sectional view taken along the I-I′ line shown in FIG. 1. In FIG. 1 and/or FIG. 2, a first direction through a third direction DR1, DR2, and DR3 may be defined. The first direction DR1 and the second direction DR2 may be directions defined on a plane of the display device 200, as shown in FIG. 1, and intersect with each other. The third direction DR3 may be a direction of a thickness of the display device, as shown in FIG. 2.

The display device 200 may include a substrate BS, a circuit layer CL, and a display device layer EDL. The circuit layer CL and the display device layer EDL may be disposed on the substrate BS. The substrate BS may include, but not limited to, glass, ceramic, a metal, or a polymer resin such as a polyimide. The substrate BS may be an inorganic layer, an organic layer, and a composite material layer, and may be constituted with a single layer or a multilayer.

The circuit layer CL may be disposed on the substrate BS and include a plurality of wires and a plurality of transistors. The circuit layer CL may include pixel transistors configured to drive light-emitting diodes ED1, ED2, and ED3 of the display device layer EDL. The circuit layer CL may include surrounding transistors disposed on a surrounding area NA and configured to control pixel transistors.

The display device layer EDL may include a pixel definition film PDL, light-emitting diodes ED1, ED2, and ED3, and an encapsulation layer TFE.

The pixel definition film PDL may include at least one insulating material such as a polyimide, a polyamide, an acryl resin, a benzocyclobutene-based resin, or a phenol resin.

The light-emitting diodes ED1, ED2, and ED3 may each include a first electrode EL1, a hole functional layer HFL, a light-emission layer EML1, EML2, and EML3, an electron functional layer EFL, and a second electrode EL2.

The hole functional layer HFL is configured to facilitate movement of a hole from the first electrode EL1 to the light-emission layer EML1, EML2, and EML3. The electron functional layer EFL is configured to facilitate movement of an electron from the second electrode EL2 to the light-emission layer EML1, EML2, and EML3. FIG. 2 exemplarily illustrates that the hole functional layer HFL is interposed between the first electrode EL1 and the light-emission layer EML1, EML2, and EML3, and the electron functional layer EFL is interposed between the second electrode EL2 and the light-emission layer EML1, EML2, and EML3. However, embodiments of the present disclosure are not limited thereto, and positions of the hole functional layer HFL and the electron functional layer EFL may be exchanged based on whether each of the first electrode EL1 and the second electrode EL2 is positively charged or negatively charged.

In FIG. 2, the light-emission layers EML1, EML2, and EML3 of the light-emitting diodes ED1, ED2, and ED3 are disposed in an opening part OH defined in the pixel definition film PDL. FIG. 2 is an illustration of one or more embodiments in which the hole functional layer HFL, the electron functional layer EFL, and the second electrode EL2 are each provided as a common layer throughout the light-emitting diodes ED1, ED2, and ED3. However, embodiments of the present disclosure are not limited to what is illustrated in FIG. 2, and for example, in one or more embodiments, at least one of the hole functional layer HFL and the electron functional layer EFL may be provided to be patterned inside the opening part OH defined in the pixel definition film PDL.

In one or more embodiments, at least some of the light-emitting diodes EDT, ED2, and ED3 may be configured to emit light at a different wavelength range. For example, a first light-emitting diode ED1 may be configured to emit red light, a second light-emitting diode ED2 may be configured to emit green light, and a third light-emitting diode ED3 may be configured to emit blue light. However, embodiments of the present disclosure are not limited to this configuration, and for example, a first light-emitting diode through a third light-emitting diode ED1, ED2, and ED3 may be configured to emit light at a substantially same wavelength range, such as blue light.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include one or more compounds such as acrylic compounds, epoxy compounds, and/or the like, but embodiments of the present disclosure are not limited thereto. In one or more embodiments, the encapsulation organic film may include, but may not be limited to, one or more of photo-polymerizable organic materials. The encapsulation inorganic film may include, but may not be limited to, silicon nitride, silicon oxynitride, silicon oxide, titanium oxide, and/or aluminum oxide.

Referring to FIG. 1 and FIG. 2, the display device 200 may be defined with a display area DA and a surrounding area NA defined outside of the display area. The display area DA may be an area configured to display an image, and the surrounding area NA may be an area not configured to display an image. In certain embodiments, the surrounding area NA may or may not be provided.

The display area DA may have pixel areas PA1, PA2, and PA3 and a non-pixel area NPA defined therein. As light-emitting diodes ED1, ED2, and ED3 may be disposed to correspond to the pixel areas PA1, PA2, and PA3, respectively, the pixel areas may be areas configured to display emitted light. The non-pixel area NPA may be an area defined among the pixel areas PA1, PA2, and PA3 and correspond to the pixel definition film PDL.

Although FIG. 1 and FIG. 2 depict pixel areas, PA1, PA2, and PA3, having a same area, embodiments of the present disclosure are not limited to what are illustrated in FIG. 1 and FIG. 2. For example, in one or more embodiments, some of the pixel areas PA1, PA2, and PA3 may have different areas.

In one or more embodiments, the display device 200 according to one or more embodiments of the present disclosure may further include an optical layer (not shown) disposed on the display device layer EDL. The optical layer (not shown) may be configured to reduce reflected light of external light. The optical layer (not shown) may include a polarizing layer and/or a color filter layer.

Although it is not illustrated in FIG. 2, in one or more embodiments, the display device 200 according to one or more embodiments of the present disclosure may further include a touch-sensor layer (not shown) disposed on the display device layer EDL. The touch-sensor layer (not shown) may be configured to detect a coordination of a touch where a touch occurs. The touch-sensor layer (not shown) may be interposed between the display device layer EDL and the optical layer (not shown).

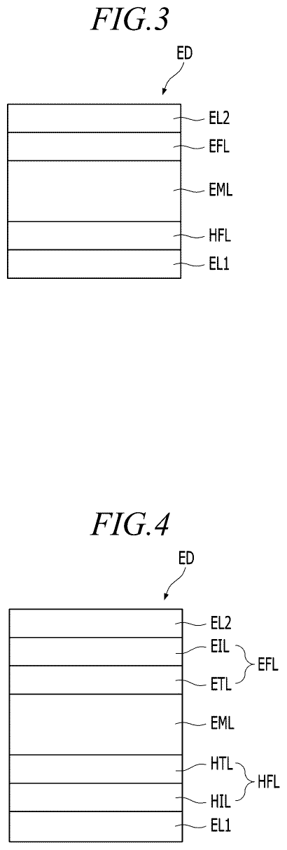

FIG. 3 through FIG. 6 are cross-sectional views illustrating a light-emitting diode according to one embodiment. The light-emitting diode ED according to one or more embodiments of the present disclosure illustrated in FIG. 0.3 may include a first electrode EL1, a hole functional layer HFL, a light-emission layer EML, an electron functional layer EFL, and a second electrode EL2 that are sequentially laminated (e.g., in the stated order).

In the light-emitting diode ED according to one or more embodiments of the present disclosure illustrated in FIG. 4, the hole functional layer HFL may include a hole injection layer HIL and a hole transport layer HTL, and the electron functional layer EFL may include an electron transport layer ETL and an electron injection layer EIL. The hole functional layer HFL may further include at least one of a buffer layer (not shown) and an electron block layer EBL in addition to the hole injection layer HIL and the hole transport layer HTL. The buffer layer (not shown) may increase light-emission efficiency by compensating a resonance distance based on a wavelength of emitted light. A material included in the hole functional layer HFL may be used as a material included in the buffer layer (not shown). The electron block layer EBL is a layer configured to prevent injection of an electron from the electron functional layer EFL to the hole functional layer HFL.

An emission auxiliary layer (not shown) is a layer configured to compensate an optical resonance distance according to a wavelength of light emitted from the light-emitting layer to increase light-emitting efficiency, and the electron blocking layer EBL is a layer configured to prevent or reduce leakage of an electron from the light-emission layer to the hole functional layer HFL. The material that may be included in the described hole functional layer HFL may be also included in the emission auxiliary layer and the light blocking layer EBL. The light-emission layer EML may be provided on the hole functional layer HFL. The light-emission layer EML may have a single layer structure composed of a single type of material, or a multilayer structure having a plurality of layers composed of a plurality of different materials.

In the light-emitting diode ED according to one or more embodiments shown in FIG. 5, the hole functional layer HFL may include a hole injection layer HIL, a hole transport layer HTL, and an electron block layer EBL, and the electron functional layer EFL may include a hole block layer HBL, an electron transport layer ETL, and an electron injection layer EIL.

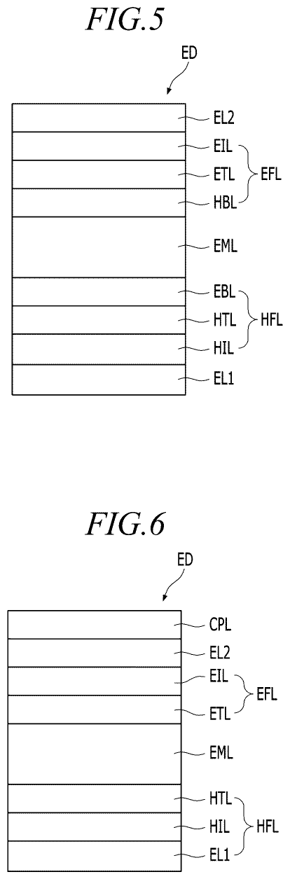

In one or more embodiments illustrated in FIG. 6, compared to the structure of the light-emitting diode ED shown in FIG. 2, the light-emitting diode ED may further include a capping layer CPL disposed on the second electrode EL2.

The first electrode EL1 is conductive (e.g., is a conductor). The first electrode EL1 may include a metal material, a metal alloy, or a conductive compound. The first electrode EL1 may be an anode or a cathode.

The first electrode EL1 may be a reflective electrode, a semi-transmissive electrode, or a transmissive electrode. If (e.g., when) the first electrode EL1 is a transmissive electrode, material(s), such as indium tin oxide (ITO), indium zinc oxide (IZO), zinc oxide (ZnO), and indium tin zinc oxide (ITZO), may be included. If (e.g., when) the first electrode EL1 is a semi-transmissive electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca (lamination structure of lithium fluoride (LiF) and Ca), LiF/Al (lamination structure of LiF and Al), molybdenum (Mo), titanium (Ti), tungsten (W), and/or a (e.g., any suitable) combination and/or mixture thereof (e.g., a mixture of Ag and Mg)). In one or more embodiments, the first electrode EL1 may have a multilayer structure including a reflective film or a semi-transmissive film including one or more of the aforementioned materials and a transparent conductive film including ITO (indium tin oxide), IZO (indium zinc oxide), ZnO (zinc oxide), ITZO (indium tin zinc oxide), and/or the like. For example, in one or more embodiments, the first electrode EL1 may have a triple layer structure of ITO/Ag/ITO or a multiple layer structure of a triple layer structure of ITO/Ag/ITO, but embodiments of the present disclosure are not limited to this configuration.

The hole functional layer HFL may be provided on the first electrode EL1. The hole functional layer HFL may include at least one of a hole injection layer HIL, a hole transport layer HTL, a buffer layer, a light-emission auxiliary layer, or an electron blocking layer EBL.

The hole functional layer HFL may have a single layer structure including (e.g., consisted of) a single layer including (e.g., consisting of) a single material, a single layer structure including (e.g., consisted of) a single layer including a plurality of different materials, or a multi-layer structure including (e.g., consisted of) a plurality of layers including a plurality of different materials.

For example, in one or more embodiments, the hole functional layer HFL may have a structure in which a hole injection layer HIL/hole transport layer HTL, a hole injection layer HIL/hole transport layer HTL/buffer layer, a hole injection layer HIL/buffer layer, a hole transport layer HIL/buffer layer, or a hole injection layer HIL/hole transport layer HTL/electron blocking layer EBL are laminated in order (e.g., in the stated order) from the first electrode EL1. However, embodiments of the present disclosure are not limited thereto.

The hole functional layer HFL may be manufactured using one or more suitable methods, such as a vacuum deposition method, a spin coating method, a Langmuir-Blodgett (LB) method, an inkjet printing method, a casting method, a laser printing method, and/or a laser induced thermal imaging (LITI) method.

The hole functional layer HFL may have a thickness of about 50 åangströms (Å) to about 10000 Å, e.g. about 100 Å to about 5000 Å. If (e.g., when) the hole functional layer HFL includes a hole injection layer HIL, a hole transport layer HTL, or any combination thereof, the hole injection layer HIL may have a thickness of about 100 Å to about 9000 Å, e.g., about 100 Å to about 1000 Å, and the hole transport layer may have a thickness of about 50 Å to about 2000 Å, e.g., about 100 Å to about 1500 Å. When the thicknesses of the hole functional layer HFL, the hole injection layer HIL, and the hole transport layer HTL satisfy their respective above-described ranges, satisfactory level of hole transport properties may be obtained without a substantial increase in driving voltage.

In one or more embodiments, the hole functional layer HFL may further include, in addition to one or more of the above-described materials, a charge-generation material to increase conductivity. The charge-generation material may be uniformly (e.g., substantially uniformly) or non-uniformly dispersed in the hole functional layer HFL.

As described above, in one or more embodiments, the hole functional layer HFL may further include at least one of a buffer layer or an electron blocking layer EBL in addition to the hole injection layer HIL and the hole transport layer HTL. The buffer layer may compensate for a resonance distance according to a wavelength of light emitted from the light-emitting layer EML to increase light-emitting efficiency. A material that may be included in the hole functional layer HFL may be used as a material included in the buffer layer.

The electron blocking layer EBL is a layer that is configured to prevent or reduce the injection of electrons from the electron functional layer EFL to the hole functional layer HFL.

The light-emission auxiliary layer is a layer configured to compensate an optical resonance distance according to a wavelength of light emitted from the light-emitting layer to increase light-emitting efficiency, and the electron blocking layer EBL is a layer configured to prevent or reduce leakage of an electron from the light-emitting layer to the hole functional layer HFL. The described material that may be included in the hole functional layer HFL may be included in the light-emission auxiliary layer and the light blocking layer EBL.

The light-emitting layer EML may be provided on the hole functional layer HFL. The light-emitting layer EML may have a single layer including (e.g., consisting of) a single material, a single layer including (e.g., consisting of) a plurality of different materials, or a multilayer structure having a plurality of layers including (e.g., consisting of) a plurality of different materials.

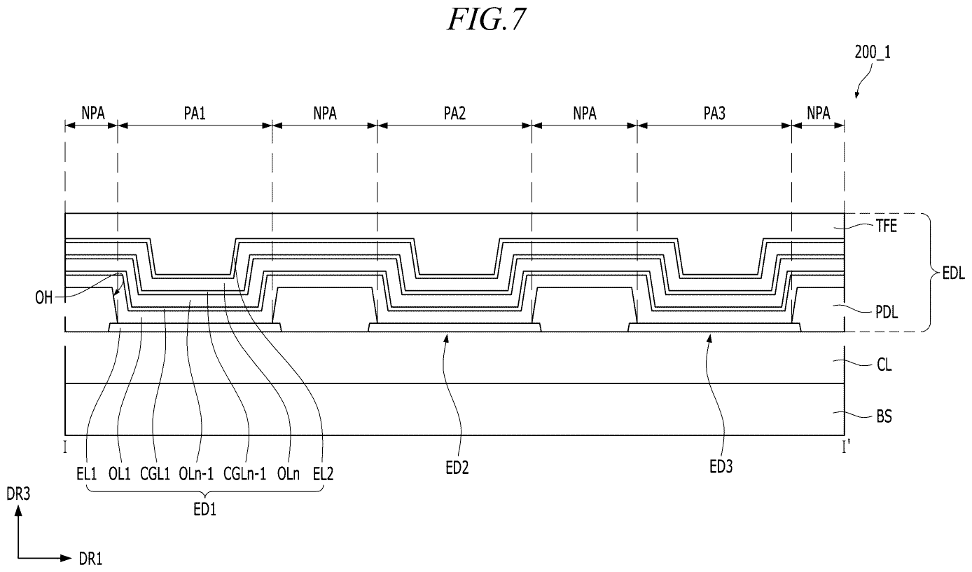

FIG. 7 is a cross-sectional view illustrating a portion of a display device 200_1 in accordance with one or more embodiments of the present disclosure. A display device 200_1 will be described with reference to a first light-emitting diode ED1 among a plurality of light-emitting diodes ED1, ED2, and ED3. The first light-emitting diode ED1 may include n light-emitting structures (OL1, . . . , OLn−1, and OLn) laminated between a first electrode EL1 and a second electrode EL2, and n−1 charge generating layers (CGL1, . . . , and CGLn−1). Here, n may be a natural number.

Each of the light-emitting structures OL1, . . . , OLn−1, and OLn may include a hole functional layer HFL and an electron functional layer EFL. Light-emitting layer EML1 (in FIG. 2) may be disposed between the hole functional layer HFL and the electron functional layer EFL.

For example, the first light-emitting diode ED1 included in the display device 200_1 of one or more embodiments may be a light-emitting diode having a tandem structure including a plurality of light-emission layers.

The charge generation layers CGL1, . . . , and CGLn−1 may be each respectively interposed between neighboring light-emitting structures OL1, . . . , OLn−1, and OLn. The charge generation layers CGL1, . . . , and CGLn−1 may each include a p-type (kind) charge generation layer and/or an n-type (kind) charge generation layer.

FIG. 7 illustrates the display device 200_1 including three light-emitting structures OL1, OLn−1, and OLn and two charge generation layers CGL1 and CGLn−1 if (e.g., when) n is 2. Unlike what is illustrated in FIG. 7, in one or more embodiments, if (e.g., when) n is 1, the n−1-th light-emitting structure OLn−1 and n−1-th charge generation layer CGLn−1 may not be provided, and n-th light-emitting structure OLn may make direct contact with the first charge generation layer CGL 1. In addition, unlike what is illustrated in FIG. 7, in one or more embodiments, if (e.g., when) n is 3, a light-emitting structure and a charge generation layer may be sequentially added between the n−1-th charge generation layer CGLn−1 and n−1-th light-emitting structure OLn−1.

In one or more embodiments, the light-emitting structures OL1, . . . , OLn−1, and OLn, included in the first light-emitting diode ED1, may be included to emit light at substantially the same wavelength range. However, embodiments of the present disclosure are not limited thereto, and at least some of the light-emitting structures OL1, . . . , OLn−1, and OLn, included in the first light-emitting diode ED1, may be included to emit light with a different wavelength from the others.

In one or more embodiments, each of the light-emitting structures OL1, . . . , OLn−1, and OLn may allow each of the light-emitting diodes ED1, ED2, and ED3, including the light-emitting structures OL1, . . . , OLn−1, and OLn, respectively, to emit light at different ranges of wavelength. For example, the first light-emitting structure OL1 included in the first light-emitting diode ED1 and the first light-emitting structure OL1 included in the second light-emitting diode ED2 may be to emit light at different ranges of wavelength. However, embodiments of the present disclosure are not limited thereto, for example, each of the light-emitting structures OL1, . . . , OLn−1, and OLn may allow each of the light-emitting diodes EDT, ED2, and ED3, including the light-emitting structures OL1, . . . , OLn−1, and OLn, respectively, to emit light at substantially the same wavelength range.

Although it is illustrated in FIG. 7 that all (e.g., each) of the light-emitting diodes ED1, ED2, and ED3 have the same structure, embodiments of the present disclosure are not limited to what is illustrated in the drawing. In one or more embodiments, some of the light-emitting diodes ED1, ED2, and ED3 may include k light-emitting structures (k is a natural number), and the others may include m light-emitting structures (m is a natural number different from k).

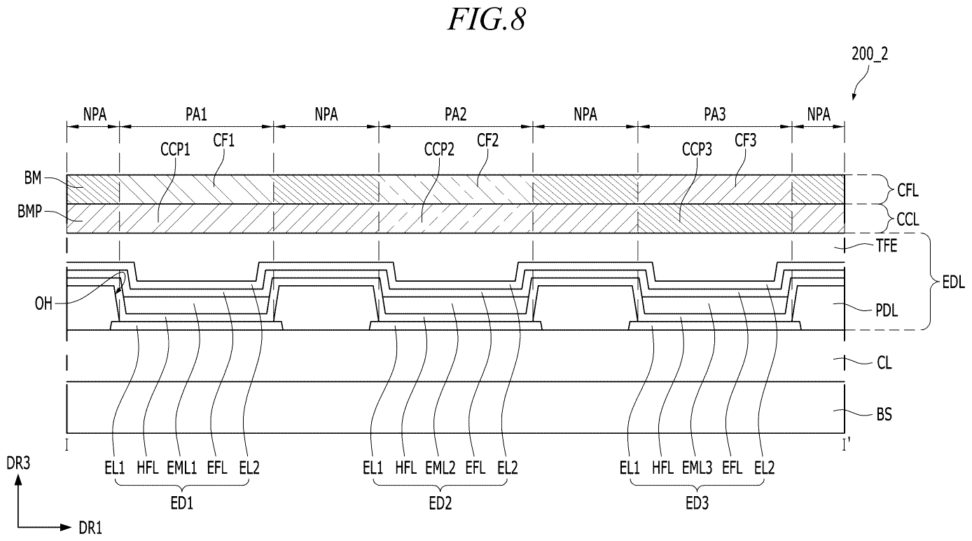

FIG. 8 is a cross-sectional view illustrating a portion of a display device in accordance with one or more embodiments of the present disclosure. A display device 200_2 according to one or more embodiments in FIG. 8 is described based on a difference from the display device 200 described with reference to FIG. 2. An undescribed configuration follows the descriptions of FIG. 2.

The display device 200_2 may further include a light controlling layer CCL and a color filter layer CFL arranged on the display device layer EDL.

The light controlling layer CCL may include a plurality of light controlling parts CCP1, CCP2, and CCP3. FIG. 8 illustrates that the light controlling parts CCP1, CCP2, and CCP3 may be separated from one another and a partition pattern BMP may be arranged between the light controlling parts. Nonetheless, embodiments of the present disclosure are not limited to what is illustrated in FIG. 8, for example, in one or more embodiments, edges of the light controlling parts may overlap with one another or edges of the light controlling parts may overlap with the partition pattern.

The light controlling layer CCL may include a first through a third light controlling parts CCP1 through CCP3 overlapping with the first through the third light-emitting diodes ED1 through ED3, respectively.

At least one of the first through the third light controlling parts CCP1 through CCP3 may transform a wavelength of incident light (e.g. blue light) and then emit light of different color (e.g. red light or green light). In addition, at least one of the first through the third light controlling parts CCP1 through CCP3 may be to transmit incident light (e.g. blue light) without transforming its wavelength.

In one or more embodiments, at least one of the first through the third light controlling parts CCP1 through CCP3 may include a light converter, such as a quantum dot or a phosphor. The light converter may transform the wavelength of light provided and then emit the transformed (converted) light. The first through the third light controlling parts CCP1 through CCP3 may each further include a scatter and a base resin configured to disperse the scatter.

In one or more embodiments, the light controlling layer CCL may further include a barrier layer configured to prevent or reduce penetration of moisture and/or oxygen.

The color filter layer CFL may be disposed on the light controlling layer CCL. The color filter layer CFL may include a plurality of color filters CF1, CF2, and CF3. FIG. 8 illustrates that the color filters CF1, CF2, and CF3 are spaced and/or apart (e.g., spaced apart or separated) and have a blocking part BM arranged between the color filters. However, embodiments of the present disclosure are not limited to what is illustrated in FIG. 8, and in one or more embodiments, edges of the color filters may overlap with one another, and edges of the color filters may overlap with the blocking part.

The color filter layer CFL may include a first through a third color filters CF1 through CF3 overlapping with the first through the third light-emitting diodes ED1 through ED3, respectively.

The first through the third color filters CF1 through CF3 may selectively pass light with a selected color. However, embodiments of the present disclosure are not limited thereto, and at least one of the first through the third color filters CF1 through CF3 may be provided as transparent or translucent.

An electronic device according to one or more embodiments may include a display device, a processor configured to control the display device, a memory configured to store data necessary for operation of the display device or the processor, and a power module configured to generate or supply power.

An electronic device according to the above embodiments may be applicable to various electronic devices. An electronic device according to one or more embodiments may include electronic devices to be described herein and further include a module or a device having an additional function in addition to the electronic device.

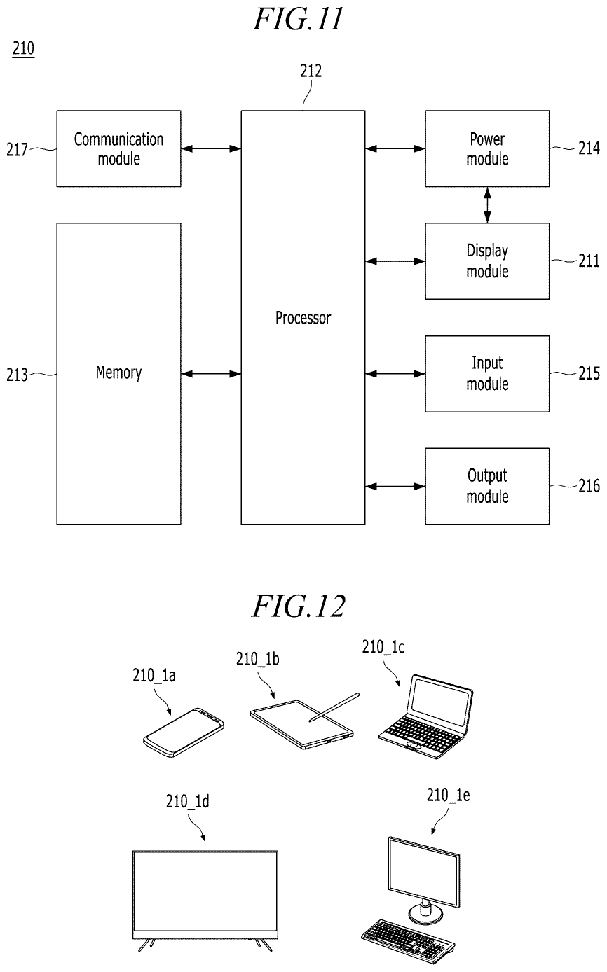

FIG. 11 is a block diagram of an electronic device according to one embodiment. Referring to FIG. 11, the electronic device 210 according to one embodiment may include a display module 211, a processor 212, a memory 213, and a power module 214. The electronic device 210 may further include an input module 215, an output module 216 and/or a communication module 217.

The electronic device 210 may be configured to output various information in a form of an image through the display module 211. In case that the processor 212 operates an application stored in the memory 213, the application may be configured to provide image information to a user through the display module 211. The power module 214 may include a power supply module, such as a power adaptor or a battery device, and a power conversion module configured to convert power supplied from the power supply module to generate power necessary for operation of the electronic device 210. The input module 215 may provide input information to the processor 212 and/or the power module 211. The output module 216 (or non-image output module) may be configured to receive acoustic, haptic, or light-emission information in addition to image provided from the processor to provide the information to a user. The communication module 217 is a module configured to transmit and receive information between the electronic device 210 and an external device and include a receiver and a transmitter.

At least one of the above-described components of the electronic device 210 may be included within the electronic device according to the above-described embodiments. Additionally, certain individual modules included functionally within a single module may be provided within the display device while other individual modules may be provided outside the electronic device. For instance, the display device may include the display module 211, and the processor 212, memory 213, and power module 214 may be provided as other devices within the electronic device 210 but not within the display device.

FIG. 12 through FIG. 14 are schematic diagrams of electronic devices according to various embodiments. FIG. 12 through FIG. 14 illustrate examples of various electronic devices applied with electronic devices according to embodiments.

As examples of an electronic device, FIG. 12 illustrate a smartphone 210_1A, a tablet PC 210_1B, a laptop 210_1C, a TV 210_1D, and a desktop monitor 210_1E.

A smartphone 210_1A may include an input module, such as a touch sensor, and a communication module in addition to a display module 211. A smartphone 210_1A may be configured to process information received from the communication module or other input modules to display information through the display module of the electronic device.

Similar to the smartphone 210_1A, a tablet PC 210_1B, a laptop 210_1C, a TV 210_1D, a desktop monitor 210_1E may also include a display module and an input module, and in some embodiments, a communication module may be further included.

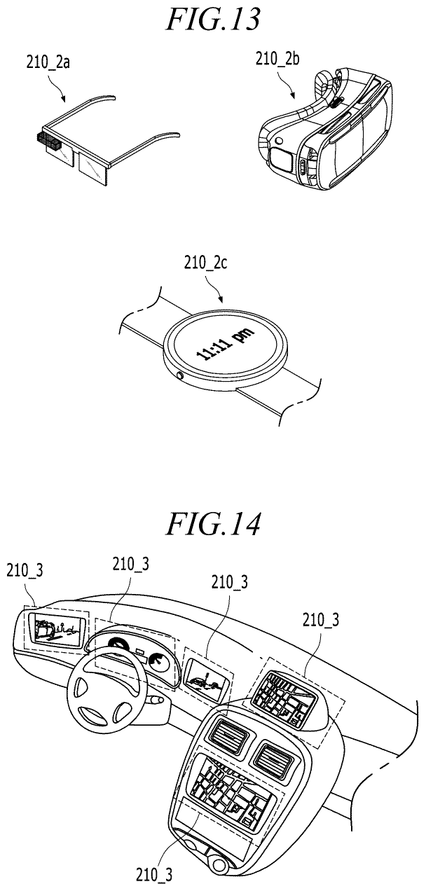

FIG. 13 illustrates an example in which an electronic device including a display module is applied to a wearable electronic device. Examples of a wearable electronic device may be smart glasses 210_2A, a head-mounted display 210_2B, or a smart watch 210_2C.

Smart glasses 210_2A and ahead-mounted display 210_2B may include a display module configured to emit a display image and a reflector configured to reflect a display screen towards eyes of a user. Accordingly, an image of virtual reality or augmented reality may be provided to a user.

A smart watch 210_2C may include a biometric sensor as an input device and be configured to provide biometric information recognized through the biometric sensor to a user through a display module.

FIG. 14 illustrates an example in which an electronic device including a display module is applied to a vehicle. For example, an electronic device 210_3 may be applied to, for example, a vehicle instrument panel, center fascia, center information display (CID) disposed on a dashboard of a vehicle, or a room mirror display replacing a side mirror.

Although it is not illustrated, an electronic device applicable with an electronic device according to one or more embodiments may include not only devices mainly for displaying an image, such as a billboard, an electronic board, or a game console, but also various home appliances displaying information through a display module, such as a refrigerator, a washing machine, a dryer, an air conditioner, or a robot vacuum cleaner. In addition, in case that a display module allows penetration of light, an electronic device according to one or more embodiments may be applicable to an electronic device, such as a smart window, or a transparent electronic device displaying an image along with a background. For example, an electronic device according to one or more embodiments may be applicable to one or more suitable electronic devices, such as a plane panel display, a curved display, a television, a billboard, a computer monitor, a medical monitor, ahead mounted display (HMD), a light for indoor light, an outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle, an outdoor electronic device, a theater screen, a stadium screen, a screen, a signboard, and home appliances displaying information through a display module, such as a refrigerator, a washing machine, a dryer, an air conditioner, or a robot vacuum cleaner. However, types of an electronic device according to one embodiment are not limited to the above examples, and an electronic device according to one or more embodiments of the present disclosure may be applicable to various undescribed electronic devices.

According to another aspect of the present disclosure, a manufacturing method of an electronic device includes a cleaning process for cleaning a material to be cleaned using a cleaning composition for an organic or inorganic material, the cleaning composition including an amide-based compound and an amine-based compound, wherein a volume ratio of the amide-based compound to the amine-based compound is 1:1 to 1:99, the amide-based compound is an amide-based compound represented by Formula 1 below, and the amine-based compound is an amine-based compound represented by Formula 2 below.

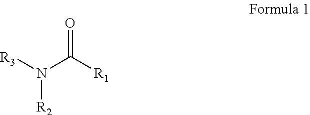

In Formula 1, R₁ through R₃ may each be independently of a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group. There may be at least one of R₁ through R₃ that is not a hydrogen atom, and the R₁ through R₃ may form 5- to 8-membered cyclic rings.

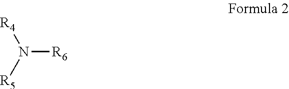

In Formula 2, R₄ through R₆ may each be independently of a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms. There may be at least one of R₄ through R₆ that is not a hydrogen atom, and the R₄ through R₆ may form 5- to 8-membered cyclic rings.

A manufacturing method of an electronic device including a cleaning process to clean a material to be cleaned using the cleaning composition for organic or inorganic materials may use the described cleaning method, but the present disclosure is not limited thereto.

Hereinafter, the present disclosure will be described with reference to embodiments in detail.

### MANUFACTURING EMBODIMENT

### Manufacturing Embodiment 1. Manufacture of Cleaning Composition for Mask

Embodiment 1: A cleaning composition for organic or inorganic materials was prepared with a volume ratio of an amide-based compound to an amine-based compound of 1:19. The amide-based compound was N,N-dimethylpropionamide (DMPA). The amine-based compound was N-(3-aminopropyl)morpholine (aminopropylmorpholine, APM).

Embodiment 2: Except for a volume ratio of an amide-based compound to an amine-based compound as 1:9, a cleaning composition for organic or inorganic materials was prepared through the same process as shown in Embodiment 1.

Embodiment 3: Except for a volume ratio of an amide-based compound to an amine-based compound as 1:5.67, a cleaning composition for organic or inorganic materials was prepared through the same process as shown in Embodiment 1.

Embodiment 4: Except for a volume ratio of an amide-based compound to an amine-based compound as 1:4, a cleaning composition for organic or inorganic materials was prepared through the same process as shown in Embodiment 1.

Comparative Example 1: Except for using commercially available N-methyl-2-pyrrolidone (NMP), a cleaning composition for organic or inorganic materials was prepared through the same process as shown in Embodiment 1.

Comparative example 2: Except for including an amide-based azeotropic mixture, a cleaning composition for organic or inorganic materials was prepared through the same process as shown in Embodiment 1.

### Experimental Example 1

### Experimental Example 1. Evaluation of Dissolution Time of Cleaning Composition for Mask

After adding Comparative Example 1 and Embodiment 1 through Embodiment 3 in an amount of 10 ml in different 50 ml vials, 8 types of organic materials were added to the vials. After closing a lid of each vial, and the vials were placed in a constant-temperature water tank. Subsequently, effects on decreasing dissolution time of the organic materials were determined, and results were shown in Table 1.

TABLE 1

| | Comparative Example and Embodiment (unit: minute) | | | |
|---|---|---|---|---|
| Organic | Comparative | | | |
| Material | Example 1 | Embodiment 1 | Embodiment 2 | Embodiment 3 |
| A1 | 3 | 2.7 | 3.3 | 3 |
| A2 | 5.3 | 5 | 4 | 4.7 |
| A3 | 1 | 1 | 1 | 1 |
| A4 | 1 | 1 | 1 | 1 |
| A5 | 1 | 1 | 1 | 1 |
| A6 | 1 | 1 | 1 | 1 |
| A7 | 6 | 7 | 5.7 | 9 |
| A8 | 10 | 10.3 | 8.7 | 9.3 |

Referring to Table 1, dissolution times of an Organic Material A1 and an Organic Material A2 were faster in Embodiment 1 through Embodiment 3 than Comparative Example 1. For Organic Material 3 through Organic Material A6, dissolution times were shown to be same in Embodiment 1 through Embodiment 3 and Comparative Example 1. Dissolution times of Organic Material A7 and Organic Material A8 were faster in Embodiment 2 and Embodiment 3 than Comparative Example 1. In light of the above, the results indicated that, in comparison to conventional Comparative Example 1 having very excellent cleaning capability. Embodiment 1 through Embodiment 3 of the present disclosure were provided with superior or equivalent cleaning capability while Embodiment 1 through Embodiment 3 of the present disclosure were harmless to a human being and had little environmental toxicity.

### Experimental Example 2. Evaluation of PNL Reliability

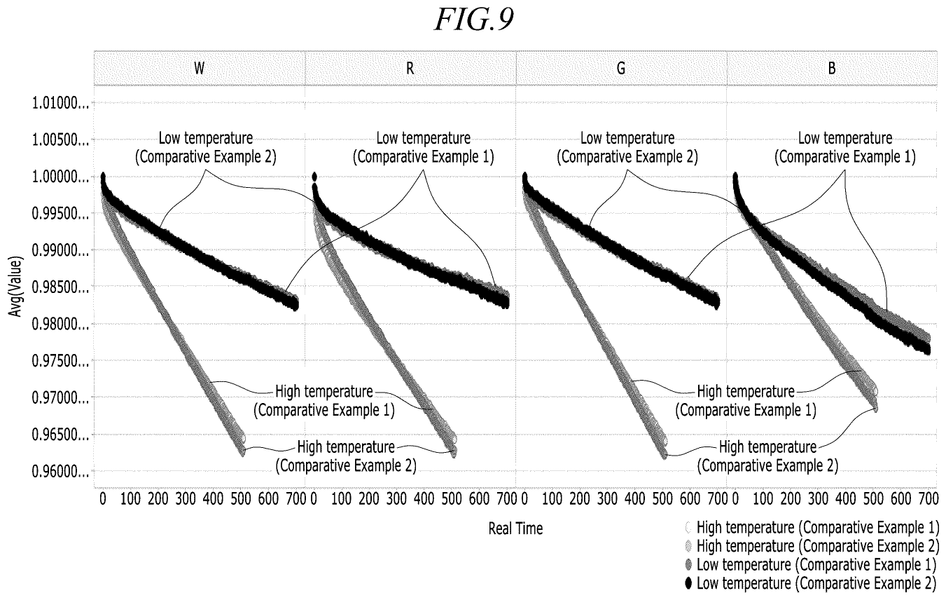

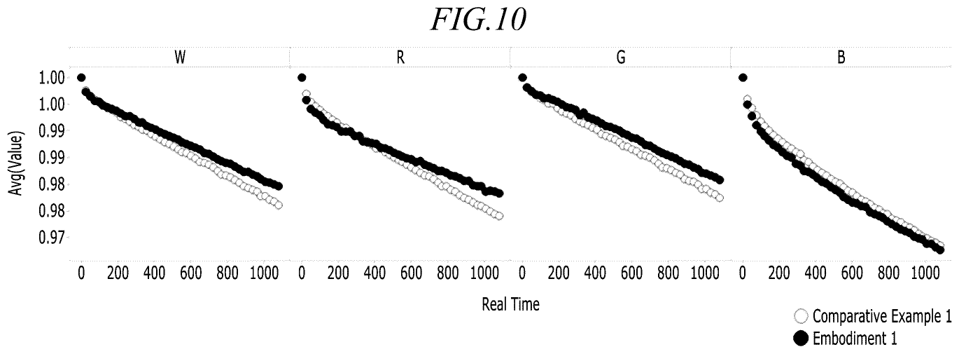

After preparation of light-emitting diode samples before and after cleaning, a mask was cleaned through ultrasonic cleaning or heat cleaning. Subsequently, photoluminescence (PNL) was measured to evaluate performance degradation of W (white), R (red), G (green), and B (blue) light-emitting diodes. The performance degradation was measured up to 6000 hours. Among the measurements, evaluation results based on 700 hours and 1000 hours were shown in FIG. 9 and FIG. 10.

FIG. 9 is a graph that indicates the PNL reliability evaluation as a function of time (hours) results of Comparative Example 1 and Comparative Example 2 of the present disclosure at a high temperature and a room temperature. Referring to FIG. 9, the results indicate that, in comparison to Comparative Example 1, luminance (brightness) of Comparative Example 2 decreases more as time passes.

FIG. 10 is a graph of the reliability evaluation as a function of time (hours). The graph includes the PNL reliability evaluation results of Comparative Example 1 and Embodiment 1 of the present disclosure. Referring to FIG. 10, the results indicate that, in comparison to Comparative Example 1, a degree of decrease in luminance (brightness) of Embodiment 1 is much smaller. Additionally, results indicate that, in comparison to Comparative Example 1, also in case of B (blue), a degree of decrease in luminance of Embodiment was similar up to 1000 hours, but much less as time approaches 6000 hours.

As a result, it could be confirmed that, in comparison to Comparative Example 1, Embodiment 1 had excellent PNL reliability.

### Experimental Example 3. Evaluation of Remaining Cleaning Agent and Evaluation of Surface Tension

In order to determine surface residence degree, permeability, and dryness after cleaning with a composition according to the present disclosure, fluidities of cleaning agents of Embodiment 1 through Embodiment 4 and Comparative Example 1 were evaluated along with surface tension. Results were shown in Table 2.

TABLE 2

| | Organic Agent | | Additive Agent | | Surface | Cleaning |
|---|---|---|---|---|---|---|
| | Raw | Content | Raw | Content | Tension | Agent |
| Category | Material | (wt. %) | Material | (wt. %) | (dyne) | Fluidity |
| Comparative | NMP | 100 | — | — | 40 | Δ |
| Example 1 | | | | | | |
| Embodiment 1 | DMPA | 95 | APM | 5 | 32 | ⊚ |
| Embodiment 2 | DMPA | 90 | APM | 10 | 32 | ⊚ |
| Embodiment 3 | DMPA | 85 | APM | 15 | 34 | ⊚ |
| Embodiment 4 | DMPA | 80 | APM | 20 | 34 | ◯ |

Referring to Table 2, the surface tension, in comparison to Comparative Example 1, was decreased in all of Embodiment 1 through Embodiment 4, and the results indicated that cleaning agent fluidity was superior in all of Embodiment 1 through Embodiment 4.

As a result, the results indicated that the cleaning solution composition according to the present disclosure had a lesser surface tension with high permeability and excellent dryness, and thus, more advantageous also in drying a gap in a mask.

In addition, a cleaning solution composition according to the present disclosure had excellent cleaning agent fluidity. Therefore, an amount of a composition remaining on a surface after cleaning of a mask was much less. This confirmed that using a composition according to the present disclosure could minimize an amount of a cleaning composition remaining on a surface after cleaning of a mask in comparison to Comparative Example 1.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Therefore, the technical scope of the present disclosure should be interpreted by the scope of the claims and equivalents thereof, instead of being restricted the disclosed description in Detailed Description.

What is claimed is:

1. A cleaning composition for an organic or inorganic material, the cleaning composition comprising:
an amide-based compound; and
an amine-based compound,
wherein a volume ratio of the amide-based compound to the amine-based compound is 1:1 to 1:99,
wherein the amide-based compound is an amide-based compound represented by Formula 1;
wherein the amine-based compound is an amine-based compound represented by Formula 2; 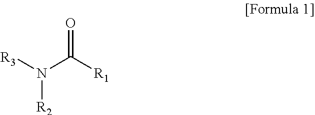
wherein in Formula 1, each of R₁ through R₃ is independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group, and
wherein at least one of R₁ through R₃ is not a hydrogen atom, and optionally the R₁ through R₃ form one or more 5- to 8-membered cyclic rings; and 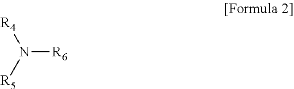
wherein in Formula 2, each of R₄ through R₆ is independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, or a C2 to C10 alkynyl group including a heterocyclic compound having 2 to 20 ring-forming atoms, wherein at least one of R₄ through R₆ is not a hydrogen atom, and optionally the R₄ through R₆ together form one or more 5- to 8-membered cyclic rings.

2. The cleaning composition for an organic or inorganic material of claim 1,
wherein the heterocyclic compound is piperazine, pyrazine, morpholine, pyrone, pyrazole, imidazole, isoxazole, oxazole, isothiazole, thiazole, triazole, indole, quinoline, benzothiazole, or benzooxazole.

3. The cleaning composition for an organic or inorganic material of claim 1,
wherein the amide-based compound is a compound of Formula 1 where R₁ through R₃ each is an unsubstituted C1 to C20 alkyl group,
wherein the amine-based compound is a compound of Formula 2 where R₄ through R₆ each is a C1 to C10 alkyl group including a heterocyclic compound having 5 to 20 ring-forming atoms, and
wherein the heterocyclic compound is a pyrazine, a morpholine, pyrone, pyrazole, imidazole, isoxazole, oxazole, isothiazole, thiazole, or triazole.

4. The cleaning composition for an organic or inorganic material of claim 1,
wherein the amide-based compound is N,N-dimethylpropionamide (DMPA), N,N-dimethylisobutylamide, N,N-dimethylacrylamide, N,N-dimethylmethacrylamide, N-ethylformamide, N,N-diethylformamide, N,N-diethylacetamide, N,N-diethylpropionamide, N,N-diethylisobutylamide, N,N-diethylacrylamide, N,N-diethylmethacrylamide, 3-methoxy-N,N-dimethylpropionamide, 3-butoxy-N,N-dimethylpropionamide, or a combination thereof.

5. The cleaning composition for an organic or inorganic cleaning composition of claim 1,
wherein the amine-based compound is N-(3-aminopropyl)morpholine, 1-amino-benzotriazole, 2-amino-benzotriazole, or a combination thereof.

6. The cleaning composition for an organic or inorganic material of claim 1,
wherein the cleaning composition for an organic or inorganic material is for cleaning an OLED deposition mask.

7. The cleaning composition for an organic or inorganic material of claim 1,
wherein the cleaning composition for an organic or inorganic material is for cleaning an organic material forming a light-emission layer, a light-emission host material, a dopant, a hole transport layer, a hole block layer, an electron injection layer, or a capping layer.

8. The cleaning composition for an organic or inorganic material of claim 1,
wherein the cleaning composition for an organic or inorganic material removes a silicon-based polymer, a color resist, an organic insulating film, or a resin.

9. The cleaning composition for an organic or inorganic material of claim 7,
wherein the organic material is a phthalocyanine derivative, a phenylamine derivative, a phenoxybenzene derivative, a carbazolyl derivative, a polyaniline derivative, a starburst amine derivative, a porphyrin derivative, an oligothiophene derivative, an arylamine derivative, a hexanitrile hexaazatriphenylene derivative, a quinacridone derivative, a perylene derivative, an anthraquinone, a polythiophene derivative, or a combination thereof.

10. The cleaning composition for an organic or inorganic material of claim 1,
wherein the cleaning composition for an organic or inorganic material further comprises a water-soluble polar solvent.

11. The cleaning composition for an organic or inorganic material of claim 10,
wherein the water-soluble polar solvent is comprised in an amount of 5 to 50 volume % with respect to 100 volume % of the cleaning composition.

12. The cleaning composition for an organic or inorganic material of claim 1,
wherein the cleaning composition for an organic or inorganic material further comprises water, and the water is comprised in an amount of less than or equal to 1 volume % with respect to 100 volume % of the cleaning composition for an organic or inorganic material.

13. The cleaning composition for an organic or inorganic material of claim 1,
wherein a boiling point of the amide-based compound, the amine-based compound, or a combination thereof is higher than or equal to 100° C. and less than or equal to 300° C.

14. A cleaning composition for an organic or inorganic material of claim 1,
wherein the composition for an organic or inorganic material further comprises a pH adjusting agent.

15. A cleaning method of an organic or inorganic material comprising a cleaning process of cleaning a material to be cleaned using a cleaning composition for an organic or inorganic material, the cleaning composition comprising:
an amide-based compound and
an amine-based compound,
wherein a volume ratio of the amide-based compound to the amine-based compound is 1:1 to 1:99;
wherein the amide-based compound is an amide-based compound represented by Formula 1;
wherein the amine-based compound is an amine-based compound represented by Formula 2; 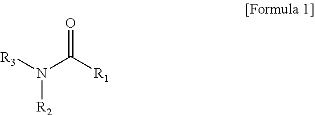
wherein in Formula 1, each of R₁ through R₃ is independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, a substituted or unsubstituted C1 to C20 amide group, a substituted or unsubstituted C2 to C20 alkenyl group, and a substituted or unsubstituted C2 to C20 alkynyl group, provided that at least one of R₁ through R₃ is not a hydrogen atom, and optionally the R₁ through R₃ form one or more 5- to 8-membered cyclic rings, and 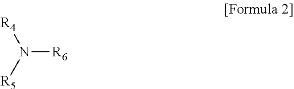
wherein in Formula 2, each of R₄ through R₆ is independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms, and optionally the R₄ through R₆ form at least one 5- to 8-membered cyclic rings.

16. The cleaning method of an organic or inorganic material of claim 15,
wherein the amide-based compound is a compound of Formula 1 where R₁ through R₃ each is an unsubstituted C1 to C20 alkyl group,
wherein the amine compound is a compound of Formula 2 where R₄ through R₆ each is a C1 to C10 alkyl group including a heterocyclic compound having 5 to 20 ring-forming atoms, and
wherein the heterocyclic compound is a pyrazine, a morpholine, pyrone, pyrazole, imidazole, isoxazole, oxazole, isothiazole, thiazole, or triazole.

17. The cleaning method of an organic or inorganic material of claim 15,
wherein the cleaning process is a cleaning process performed by dipping, spray, ultrasound, heat, or steam.

18. The cleaning method of an organic or inorganic material of claim 15,
wherein the cleaning process is performed at a temperature higher than or equal to 0° C. and less than or equal to 80° C.

19. The cleaning method of an organic or inorganic material of claim 15,
wherein a processing time of the cleaning process is longer than or equal to 50 seconds and shorter than or equal to 3600 seconds.

20. An electronic device manufactured through a manufacturing method comprising a cleaning process for cleaning a material to be cleaned using a cleaning composition for an organic or inorganic material, the cleaning composition comprising:
an amide-based compound and
an amine-based compound,
wherein a volume ratio of the amide-based compound to the amine-based compound is 1:1 to 1:99;
wherein the amide-based compound is an amide-based compound represented by Formula 1;
wherein the amine-based compound is an amine-based compound represented by Formula 2; 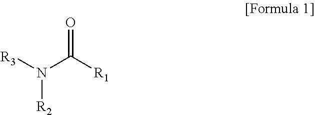
wherein in Formula 1, each of R₁ through R₃ is independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, or a substituted or unsubstituted C1 to C20 amide group wherein at least one of R₁ through R₃ is not a hydrogen atom, and optionally the R₁ through R₃ form one or more 5- to 8-membered cyclic rings, and 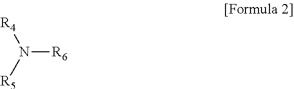
wherein in Formula 2, each of R₄ through R₆ is independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms, and at least one of R₄ through R₆ is not a hydrogen atom, and optionally the R₄ through R₆ form one or more 5- to 8-membered cyclic rings.

21. The electronic device of claim 20,
wherein the electronic device comprises a display device; a processor configured to control the display device; a memory configured to store data necessary for operation of the display device or the processor; and a power module configured to generate or supply power.

22. The electronic device of claim 20,
wherein the electronic device is at least one of a plane panel display, a curved display, a television, a billboard, a computer monitor, a medical monitor, a head mounted display (HMD), a light for indoor light, an outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle, an outdoor electronic device, a theater screen, a stadium screen, a screen, a signboard, and home appliances displaying information through a display module, such as a refrigerator, a washing machine, a dryer, an air conditioner, or a robot vacuum cleaner.

23. A manufacturing method of an electronic device comprising a cleaning process for cleaning a material to be cleaned using a cleaning composition for an organic or inorganic material, the cleaning composition comprising:
an amide-based compound and
an amine-based compound,
wherein a volume ratio of the amide-based compound to the amine-based compound is 1:1 to 1:99;
wherein the amide-based compound is an amide-based compound represented by Formula 1;
wherein the amine-based compound is an amine-based compound represented by Formula 2; 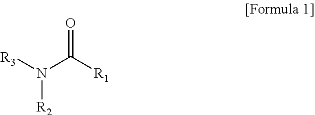
wherein in Formula 1, each of R₁ through R₃ is independently a hydrogen atom, a substituted or unsubstituted C1 to C20 alkyl group, a substituted or unsubstituted C2 to C20 alkenyl group, a substituted or unsubstituted C2 to C20 alkynyl group, a substituted or unsubstituted vinyl group, a substituted or unsubstituted C1 to C20 alkoxy group, a substituted or unsubstituted C1 to C20 alcohol group, a substituted or unsubstituted C1 to C20 amine group, a substituted or unsubstituted C4 to C20 morpholinyl group, a substituted or unsubstituted C1 to C20 amide group, a substituted or unsubstituted C2 to C20 alkenyl group, and a substituted or unsubstituted C2 to C20 alkynyl group, and here, a maximum number of hydrogen atoms substituted to the R₁ through R₃ is two, and optionally the R₁ through R₃ form one or more 5- to 8-membered cyclic rings, and 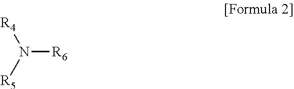
wherein in Formula 2, each of R₄ through R₆ is independently a hydrogen atom, a C1 to C10 alkyl group, a C2 to C10 alkenyl group, a C2 to C10 alkynyl group, a C1 to C10 alkyl group including a heterocyclic compound having 5 to 20 ring-forming atoms, a C2 to C10 alkenyl group including a heterocyclic compound having 5 to 20 ring-forming atoms, and a C2 to C10 alkynyl group including a heterocyclic compound having 5 to 20 ring-forming atoms, at least one of R₄ through R₆ is not a hydrogen atom, and optionally the R₄ through R₆ form one or more 5- to 8-membered cyclic rings.
